(19) United States
(12) Patent Application Publication
(10) Pub. No.: US 2025/0364304 A1
(43) Pub. Date: Nov. 27, 2025

(54) SYSTEM FOR PROCESSING WAFER-SHAPED ARTICLES

(71) Applicant: LAM RESEARCH AG, Villach (AT)

(72) Inventors: Alexander LEDERER, Villach (AT); Manuel BAUMGARTNER, Villach (AT); Martin GRADL, Villach (AT); Matthias Boris NOVAK, Villach (AT); Daniel REGENFELDER, Villach (AT); Michael PUGGL, Feistritz an der Drau (AT); Matija PONIKVAR, Villach (AT); Karl-Heinz HOHENWARTER, Dellach/Gail (AT); Ferdinand VALLANT, Villach (AT); Richard BLANK, Villach (AT); Peter THAULAD, Villach (AT); Robert Marshall STOWELL, Villach (AT)

(21) Appl. No.: 18/874,572

(22) PCT Filed: Jun. 16, 2023
(86) PCT No.: PCT/EP2023/066258

§ 371 Date: Dec. 12, 2024

(30) Foreign Application Priority Data
Jun. 17, 2022 (GB) 2208951.0

(51) Int. Cl. H01L 21/687; B25J 11/00; B25J 15/00

(52) U.S. Cl. CPC H01L 21/68707; B25J 11/0095; B25J 15/0052

(57) ABSTRACT

A system for processing wafer-shaped articles, the system comprising: three or more processing stations; and a robotic arm comprising a first set of end effectors including three or more end effectors; wherein the robotic arm is configured to pick up, from a storage unit configured to store a plurality of wafer-shaped articles, a respective wafer-shaped article with each of the three or more end effectors, and load one of the respective wafer-shaped articles into each of the three or more processing stations.

### FIELD OF THE INVENTION

The present invention relates to a system for processing wafer-shaped articles, for example semiconductor wafers.

### BACKGROUND OF THE INVENTION

Wafers such as semiconductor wafers may be subjected to various surface treatment processes, such as etching, cleaning, polishing and material deposition. A wafer is typically held using a chuck while undergoing such surface treatment processes.

At least some of these surface treatment processes involve applying a liquid to a surface of the wafer. For example, the surface of the wafer may be etched by applying a processing liquid such as hydrofluoric acid to selected locations on the surface of the wafer. Alternatively, the surface of the wafer may be cleaned by applying a cleaning liquid or rinse liquid such as isopropyl alcohol or de-ionised water to the surface of the wafer.

The wafer may be spun when the liquid is applied to the surface of the wafer, for example using a rotatable chuck (spin chuck), to assist distribution of the liquid over the surface of the wafer.

In addition, the surface of the wafer may subsequently be dried by heating the wafer to cause evaporation of the liquid on the surface of the wafer, for example by using heating elements such as LEDs in the chuck to heat an underside of the wafer.

Of course, other types of processing devices or apparatuses for processing wafers are also well known in the art.

In general, a wafer is transported to a chuck or other suitable support of a processing device or apparatus using an end effector of a robotic arm. In particular, the end effector contacts an underside of the wafer to support the wafer from beneath and is used to carry the wafer.

The end effector is typically used to lower the wafer onto the chuck or other suitable support. The end effector is then withdrawn so that the wafer can be processed. Subsequently, the same or a different end effector is used to pick up the wafer from the chuck or other suitable support.

Wafers are typically transported to a processing apparatus in a container that holds a plurality of the wafers, such as a Front Opening Unified Pod (FOUP). Individual wafers are then removed from the container using the end effector of the robotic arm. After processing, the wafer may be loaded into the same or a different container for subsequent transport.

### SUMMARY OF THE INVENTION

At its most general, the present invention provides a system for processing wafer-shaped articles, where a robotic arm is configured to simultaneously transfer three or more wafer-shaped articles from a storage unit to a set of three or more processing stations. In this manner, a single robotic arm can be used to transfer three or more wafer-shaped articles from the storage unit to the processing stations, which enables the three or more wafer-shaped articles to be processed simultaneously. This may increase a throughput of the system, i.e. increase a rate of article processing. Furthermore, as the three or more processing stations can be operated simultaneously, this may allow for resource sharing between the processing stations, which may simplify a construction of the system and improve an overall efficiency of the system.

According to a first aspect of the invention, there is provided a system for processing wafer-shaped articles, the system comprising: three or more processing stations; and a robotic arm comprising a first set of end effectors including three or more end effectors; wherein the robotic arm is configured to pick up, from a storage unit configured to store a plurality of wafer-shaped articles, a respective wafer-shaped article with each of the three or more end effectors, and load one of the respective wafer-shaped articles into each of the three or more processing stations.

Thus, the robotic arm can pick up three or more wafer-shaped articles from the storage unit (i.e. one with each end effector), and then load the three or more wafer-shaped articles into the processing stations (i.e. one into each processing station). In other words, the three or more respective wafer-shaped articles are simultaneously transferred between the storage unit and the processing stations. The first aspect of the present invention may have any one, or, where compatible, any combination of the following optional features.

The system of the invention may also be referred to as an apparatus instead of a system.

Herein, a wafer-shaped article may refer to a wafer such as a semiconductor wafer. The wafer-shaped article may comprise a semiconductor substrate.

The processing stations may be wafer processing stations. A processing station may be, or comprise, a processing module, or processing apparatus, or processing device, for example.

Each of the three or more processing stations is configured to process an individual wafer-shaped article. Thus, when one of the respective wafer-shaped articles is loaded into one of the processing stations by the robotic arm, the processing station can process the wafer-shaped article.

The three or more processing stations may be configured to perform a same process, i.e. so that the wafer-shaped articles loaded into each processing station undergo a same process.

Each of the three or more processing stations may include any suitable components for performing a desired process on a wafer-shaped article. For instance, each of the three or more processing stations may include a respective device for processing a wafer-shaped article.

As an example, each processing station may be configured to perform an etching and/or cleaning process on the wafer-shaped article. Each processing station may be configured to dispense a liquid onto a surface of the wafer-shaped article, such as an etching liquid or a cleaning liquid. As another example, each processing station may be configured to perform a bevel etch process on the wafer-shaped article. Of course, other types of processing are possible and well known in the art.

Processing a wafer-shaped article may comprise adding or removing material from the wafer-shaped article, for example etching material from the wafer-shaped article or depositing material on the wafer-shaped article.

Processing a wafer-shaped article may comprise cleaning the wafer-shaped article, for example using a cleaning or rinse liquid such as a solvent or water.

Each of the processing stations may comprise a (respective) fluid dispenser for dispensing a fluid onto a surface of the wafer-shaped article.

The fluid dispenser may be a liquid dispenser for dispensing a liquid onto a surface of the wafer-shaped article.

Each of the processing stations may comprise more than one of the fluid dispensers (a plurality of the fluid dispensers). For example, each of the processing stations may comprise two, or more than two, of the fluid dispensers.

For example, each of the processing stations may comprise a first fluid dispenser for dispensing a first fluid, such as an acid or an etching or cleaning fluid. In addition, each of the processing stations may comprise a second fluid dispenser for dispensing a rinsing fluid or liquid, such as deionised water. The second fluid dispenser may also be for dispensing a drying gas such as Nitrogen to dry the wafer-shaped article.

Each of the processing stations may comprise a (respective) chuck, for example a rotary chuck. A rotary chuck may alternatively be referred to as a spin chuck or a rotatable chuck. The chuck may be configured to receive a respective wafer-shaped article. A rotary chuck may comprise a driving mechanism, for example a motor, for driving rotation of the rotary chuck.

Loading the respective wafer-shaped articles into each of the three or more processing stations may comprise loading the respective wafer-shaped articles onto the chuck of each of the three or more processing stations.

More generally, each of the processing stations may comprise a (respective) support that is configured to support the wafer-shaped article during a processing operation performed on the wafer-shaped article.

Loading the respective wafer-shaped articles into each of the three or more processing stations may comprise loading the respective wafer-shaped articles onto the support of each of the three or more processing stations.

The support or rotary chuck may be configured to support the wafer-shaped article spaced apart from a surface of the support or rotary chuck. For example, the support or rotary chuck may be configured to support the wafer-shaped article spaced apart from a surface of the support or rotary chuck on a cushion of gas according to the Bernoulli principle. Such a support or rotary chuck may be referred to as a Bernoulli chuck or support. Alternatively, the support or rotary chuck may be configured to support the wafer-shaped article spaced apart from a surface of the support or rotary chuck on a plurality of pins extending from the surface of the support or rotary chuck. Of course, other mechanisms for supporting the wafer-shaped article above a surface of the support or rotary chuck are also possible.

More generally, the support or rotary chuck may comprise a support or supporting arrangement or supporting mechanism for supporting a wafer-shaped article spaced apart from a top surface of the support or rotary chuck.

The respective wafer-shaped articles are picked up from a single storage unit.

The three or more end effectors are provided on or in a single robotic arm.

The storage unit is configured to store a plurality of wafer-shaped articles.

The storage unit may be removable and/or detachable from the system.

The storage unit may be a container or cassette that is configured to store a plurality of the wafer-shaped articles. The storage unit may be a container or cassette that is used to transport a plurality of wafer-shaped articles to the system and/or from the system.

The storage unit may be a container or cassette that is used to transport a plurality of wafer-shaped articles between different processing apparatuses in a wafer fabrication environment.

For example, the storage unit may be a FOUP. The storage unit may form part of the system for processing wafer-shaped articles.

The system may therefore comprise the storage unit. Alternatively, the storage unit may be separate to and/or distinct from the system.

The storage unit may comprise any suitable structure for storing wafer-shaped articles. As an example, the storage unit may comprise a rack or a plurality of shelves for storing the plurality of wafer-shaped articles.

The storage unit may be configured to store the plurality of wafer-shaped articles in a stack, e.g. in a substantially vertical stack.

The storage unit may be configured to store the plurality of wafer-shaped articles one above another.

The storage unit may be configured to store the plurality of wafer-shaped articles in a vertical column.

The storage unit may comprise a first portion configured to store un-processed wafer-shaped articles (i.e. articles that have not yet been processed by the processing stations), and a second portion configured to store processed wafer-shaped articles (i.e. articles which have been processed by the processing stations).

There may be exactly or only three of the processing stations.

There may be more than three of the processing stations. The robotic arm comprises a first set of three or more end effectors, each of which is configured to pick up an individual wafer-shaped article.

Each end effector may be adapted to pick up and support (e.g. hold) a respective wafer-shaped article, and may include any suitable element(s) and/or mechanism for performing this function.

For example, each end effector may comprise one or more support elements for holding or supporting the wafer-shaped article from underneath.

The end effectors may also be referred to as manipulators, or wafer supporters, or wafer transporters, or wafer carriers.

In some cases, each end effector may comprise a retaining mechanism for retaining (e.g. gripping, holding) the wafer-shaped article, to avoid dropping the wafer-shaped article. As an example, each end effector may comprise a vacuum holder, where a vacuum is used to retain the wafer-shaped article on the end effector. Alternatively, each end effector may comprise a plurality of pins for gripping an edge of the wafer-shaped article to retain the wafer-shaped article on the end effector. Other types of retaining mechanisms may also be used, or no such retaining mechanism may be used.

Each of the three or more end effectors in the first set may be associated with a respective one of the three or more processing stations. Thus, each end effector may then be used to load a wafer-shaped article into its associated processing station. However, in other embodiments the end effectors may be used interchangeably to load wafer-shaped articles into different ones of the processing stations.

The three or more end effectors in the first set may be disposed at a working end or distal end of the robotic arm. Each of the three or more end effectors may be movable relative to the working end or distal end of the robotic arm, to facilitate the picking up of wafer-shaped articles from the storage unit and loading the wafer-shaped articles into the processing stations with the three or more end effectors.

The three or more end effectors in the first set may be provided on, or attached to, or disposed on, a common forearm of the robotic arm.

The robotic arm may comprise any suitable type of robotic arm for transferring wafer-shaped articles between the storage unit and the processing stations. The robotic arm may comprise two or more articulated parts (e.g. members). The robotic arm may comprise one or more motors for controlling motion of the robotic arm and the end effectors.

The term robot arm may be used instead of the term robotic arm.

The robotic arm may be movable between a first position in which each of the three or more end effectors in the first set is arranged to pick up a respective wafer-shaped article from the storage unit, and a second position in which each of the three or more end effectors in the first set is arranged to load the respective wafer-shaped article into an associated one of the processing stations.

To pick up a wafer-shaped article, the end effector may be positioned beneath the wafer-shaped article and then lifted so as to contact an underside of the wafer-shaped article and support the wafer-shaped article.

The robotic arm may be configured to make any suitable movement(s) for picking up the respective wafer-shaped articles from the storage unit with the end effectors. For example, the robotic arm may be configured to insert each of the three or more end effectors into the storage unit, in order to remove a respective wafer-shaped article from the storage unit with each end effector. The specific movement of the robotic arm for picking up the wafer-shaped articles from the storage unit may be adapted to the specific arrangement of the storage unit.

Similarly, the robotic arm may be configured to make any suitable movement(s) for loading the respective wafer-shaped articles into the processing stations with the end effectors. For example, the robotic arm may be configured to lower the end effectors onto the processing stations, to place the respective wafer-shaped articles on the processing stations. The specific movement of the robotic arm for loading the wafer-shaped articles into the processing stations may be adapted to the specific arrangement of the processing stations.

The robotic arm may comprise a fixed end, relative to which its working end and the end effectors are movable. The fixed end may be a proximal end of the robotic arm.

In operation, the robotic arm may first pick up a respective wafer-shaped article from the storage unit (e.g. the first portion of the storage unit) with each of the three or more end effectors. The robotic arm may then move the end effectors from the storage unit to the processing stations, in order to load one of the respective wafer-shaped articles into each processing station. Once each processing station has been loaded with a wafer-shaped article, the system may be configured to process the wafer-shaped articles by operating the processing stations.

In this manner, a single robotic arm is configured to load wafer-shaped articles into three or more processing stations. This may simplify a construction of the system, as the robotic arm is shared between the three or more processing stations, rather than using a separate robotic arm for each processing station. In particular, by sharing the robotic arm between the three or more processing stations, the number of moving parts in the system may be significantly reduced. This may in turn facilitate maintenance of the system, as well as reduce the number of potential failure points in the system, thus improving a reliability and durability of the system. Moreover, the robotic arm of the invention enables simultaneous transfer of three or more wafers between the storage unit and the processing stations. This may contribute to increasing a throughput of the system, and enables parallel processing of wafer-shaped articles in the three or more processing stations.

The robotic arm may further be configured to, following the processing of the wafer-shaped articles, remove (e.g. pick up) the wafer-shaped articles from the processing stations and transfer them back to a storage unit (e.g. the second portion of the storage unit). More specifically, each of the end effectors may pick up a respective wafer-shaped article from one of the processing stations, and load the respective wafer-shaped article into a storage unit, for example the same storage unit that the wafer-shaped articles were removed from or a different storage unit. The first set of end effectors may be used for picking up the wafer-shaped articles from the processing stations. Alternatively, a second set of end effectors may be used, as discussed in more detail below.

The robotic arm may be configured to simultaneously load the respective wafer-shaped articles into each of the three or more processing stations. In other words, each of the three or more processing stations can be simultaneously loaded with a respective wafer-shaped article. This may reduce an amount of time required to load the three or more processing stations. Additionally, this facilitates operating the three or more processing stations simultaneously (e.g. in parallel), as the processing can be initiated simultaneously for each processing station (i.e. after loading of the wafer-shaped articles).

Simultaneous loading of the respective wafer-shaped articles into each of the three or more processing stations may be achieved by arranging the three or more end effectors in the first set such that each end effector can reach its associated processing station when the robotic arm is in the second position. Thus, a same movement (or set of movements) by the robotic arm may enable the three or more processing stations to simultaneously receive a respective wafer-shaped article.

The robotic arm may be configured to simultaneously pick up the respective wafer-shaped articles with each of the three or more end effectors from the storage unit. In other words, three or more wafer-shaped articles can be simultaneously picked up by the robotic arm (one with each end effector). This may reduce an amount of time required to pick up the wafer-shaped articles and transfer them to the three or more processing stations, thus increasing a throughput of the system.

Simultaneous picking up of the respective wafer-shaped articles may be achieved by arranging the three or more end effectors in the first set such that each end effector can reach a respective wafer-shaped article in the storage unit. Thus, the arrangement of the three or more end effectors may be specifically adapted to the storage unit, to enable simultaneous picking up of a respective wafer-shaped article by each of the end effectors. Accordingly, a same movement (or set of movements) by the robotic arm may enable three or more wafer-shaped articles to be simultaneously picked up from the storage unit.

The three or more processing stations may be configured to operate simultaneously. For example, the three or more processing stations may be configured to process wafers simultaneously, for example starting and finishing the processing at the same times. In other words, the three or more processing stations may be configured to operate in parallel. In this manner, three or more wafer-shaped articles may be processed simultaneously (one in each processing station). This may increase a throughput of the system. Additionally, this may enable various parts of the system to be shared between the three or more wafer processing systems, thus reducing component redundancy in the system and simplifying construction and maintenance of the system. For example, by operating the three or more processing stations simultaneously, a common fluid supply, and/or a common drain, and/or a common suction line may be shared between the three or more processing stations.

Therefore, the three or more processing stations may share one or more of a common fluid supply, a common drain and/or a common suction line.

More generally, the three or more processing stations may share one or more components that are necessary or used for processing the wafer-shaped article. In other words, a single one of the components may be provided for all of the three or more processing stations.

Where the three or more processing stations are configured to operate simultaneously, the system may comprise a fluid source (a liquid source), and a supply valve configured to control supply of fluid from the fluid source to each of the three or more processing stations. Thus, a single supply valve can be used for controlling supply of fluid from the fluid source to the three or more processing stations. When the supply valve is open, fluid may be supplied from the fluid source to each of the three or more processing stations. The supply valve may comprise any suitable type of valve, such as a needle valve or a ball valve. The fluid source may comprise any fluid which is to be used during processing of the wafer-shaped articles. For example, the fluid source may comprise a cleaning fluid or liquid (e.g. isopropyl alcohol (IPA), acetone) or a rinsing fluid or liquid (e.g. de-ionised water). In other embodiments the fluid source may comprise an etching fluid such as hydrofluoric acid, or another processing chemical. In some cases, the system may comprise multiple fluid sources, each of which is connected to a respective supply valve, for controlling supply of fluid from the fluid source to the three or more processing stations.

The supply valve may be configured to control a flow rate of the fluid from the fluid source to the three or more processing stations.

In addition to the shared supply valve that is configured to control supply of fluid from the fluid source to each of the three or more processing stations, each of the processing stations may have or be provided with a respective supply valve. The respective supply valve may be provided in the processing station, or in a respective flow path leading from the shared supply valve to the processing station.

The respective supply valve may be an on/off valve, for example a shut on/off valve, that is used to switch on or off the flow of the fluid to the respective processing station.

Therefore, the respective supply valve may control whether or not fluid is supplied to the processing station, and the shared supply valve may control a flow rate of the fluid that flows to the processing station when the respective supply valve is open.

Where the three or more processing stations are configured to operate simultaneously, the system may comprise a drain, and a drain valve configured to control draining of fluid from the three or more processing stations to the drain. Thus, a single drain valve can be used for controlling draining of fluids from all three or more processing stations. The drain valve may comprise any suitable type of valve, such as a needle valve or a ball valve or a suction valve.

For example, liquid may be dispensed onto a surface of a wafer-shaped article and flung off the wafer-shaped article by spinning of the wafer-shaped article. The liquid flung off the wafer-shaped article may be collected and drained via the drain.

The collected liquid may then be reused and dispensed again onto the surface of the wafer-shaped article. Where the liquid is reused, the liquid may be filtered before being reused, for example by a filter in the drain and/or a drain line.

Where the three or more processing stations are configured to operate simultaneously, the system may comprise a suction source for generating a suction (or a vacuum), and a suction valve for controlling application of the suction to the three or more processing stations.

In particular, a suction source may be used to suck liquid that has been dispensed by the processing station and collected by the processing station. For example, a suction source may be used to suck liquid into the drain and/or a drain line. Thus, a single suction valve can be used for controlling application of suction to all of the three or more processing stations. The suction valve may comprise any suitable type of valve, such as a needle valve or a ball valve.

In addition, or alternatively, each of the processing stations may have a respective suction valve. The respective suction valve may be provided in the processing station, or in a respective flow path leading from the shared suction source or shared suction valve to the processing station.

The respective suction valve may be an on/off valve, for example a shut on/off valve, that is used to switch on or off the suction to the respective processing station.

In view of the above, a single valve or set of valves (e.g. supply valve, and/or drain valve, and/or suction valve) may be needed in order to control simultaneous operation of the three or more processing stations. This may facilitate parallel processing of multiple wafer-shaped articles, as well as simplify a construction and maintenance of the system.

In some embodiments, as mentioned above, in addition to a common valve, e.g. a common supply valve, drain valve or suction valve, each of the processing stations may additionally have a respective valve, e.g. a respective supply valve, and/or drain valve and/or suction valve, to allow further control. For example, providing a respective supply valve in each of the processing stations may provide greater control of shut-off of the liquid supplied from the processing device, for example via a liquid nozzle. For example, this may reduce the risk of, and/or prevent, any droplets of liquid being dispensed after shut-off of the liquid supply.

Where the three or more processing stations are configured to operate simultaneously, the system may comprise an exhaust system for controlling application of an exhaust to the three or more processing stations.

Each of the three or more end effectors may be pivotably mounted about a first common axis. For example, each of the three or more end effectors may be pivotably mounted in, or on, or to the robotic arm so that the three or more end effectors are pivotable or rotatable about the first common axis.

Being pivotable about the first common axis may mean being rotatable about the first common axis. The first common axis may pass through a proximal end of each of the end effectors.

The first common axis may be perpendicular to a main plain of the end effector, and/or perpendicular to a wafer-shaped article when the wafer-shaped article is supported by the end effector.

The three or more end effectors may be configured to be aligned to pick up the respective wafer-shaped articles from the storage unit.

The three or more end effectors may be configured to be aligned along the first common axis to pick up the respective wafer-shaped articles from the storage unit. This may be referred to as a first configuration of the end effectors.

The end effectors being aligned may mean that the end effectors overlap, for example fully overlap or overlap to a maximum extent, when viewed along the common first axis. This may facilitate picking up wafers from a vertical stack of wafers in the storage unit.

The three or more end effectors may be configured to be fanned-out to load the respective wafer-shaped articles into each of the three or more processing stations.

The three or more end effectors may be configured to be fanned-out around the first common axis, or along the first common axis, to load the respective wafer-shaped articles into each of the three or more processing stations. This may be referred to as a second configuration of the end effectors.

The three or more end effectors being fanned out may mean that each of the three or more end effectors is at a different pivot angle about or around the first common axis.

The three or more end effectors may be configured to be at different pivot angles about the first common axis to load the respective wafer-shaped articles into each of the three or more processing stations.

The three or more end effectors may be configured to rotate in parallel, or in synchronisation, or simultaneously, between the first configuration and the second configuration of the three or more end effectors.

The three or more end effectors may be arranged one above another along the first common axis. This may facilitate picking up wafers from a vertical stack of wafers in the storage unit.

The robotic arm may comprise one or more motors for controlling pivoting or rotating of the end effectors about the first common axis.

The robotic arm may comprise a first forearm, and the three or more end effectors may be pivotably mounted to the first forearm, the three or more end effectors being pivotable or rotatable relative to the first forearm about a first common axis. Such an arrangement enables the first set of three or more end effectors to be moved together between the storage unit and the processing stations, e.g. by moving the first forearm. Additionally, by making the end effectors pivotable or rotatable relative to the first forearm the end effectors can be pivoted to facilitate picking up and loading of wafer-shaped articles. The three or more end effectors of the first set may be arranged along the first common axis, such that each of the three or more end effectors is pivotable or rotatable about the first common axis. The robotic arm may comprise one or more motors for controlling pivoting of the end effectors about the first common axis.

The three or more end effectors may be pivotable or rotatable relative to the forearm between a first arrangement (e.g. a transport arrangement) where the three or more end effectors are aligned with one another along the first common axis, and a second arrangement (e.g. a loading arrangement) where the three or more end effectors are at different pivot angles with respect to the first common axis/about the first common axis.

The three or more end effectors are placed in the first arrangement when the three or more end effectors pick up respective wafer-shaped articles from the storage unit.

The three or more end effectors may also be placed in the first arrangement when the robotic arm is transporting wafer-shaped articles between the storage unit and the processing stations.

In the first arrangement, the end effectors are aligned with one another along the first common axis, i.e. the three or more end effectors are aligned when viewed along the first common axis. In other words, the first set of end effectors are all at a same pivot angle with respect to the first common axis (about or around the first common axis) when in the first arrangement.

As mentioned above, this arrangement facilitates picking up respective wafers from a vertical stack of wafers in the storage unit.

In addition, or alternatively, the first set of three or more end effectors may be more compact when in the first arrangement, which may facilitate moving the robotic arm between the storage unit and the processing station.

In the second arrangement, the end effectors are at different pivot angles, e.g. they may be in a fanned arrangement whereby the end effectors are angularly spaced from one another around the first common axis.

This may facilitate simultaneous loading of wafer-shaped articles into the three or more processing stations. In particular, the processing stations may be spaced apart (e.g. located adjacent to one another). Therefore, in the second arrangement, each end effector can be pivoted with respect to the first common axis so that its position corresponds to its associated processing station.

For instance, an arrangement of the end effectors in the second arrangement may correspond to a spatial arrangement of the processing stations.

As an example, when the end effectors are in the second arrangement, the end effectors may be arranged such that each end effector is disposed above its associated processing station. Then, the end effectors can be lowered towards the processing stations, to simultaneously load the respective wafer-shaped articles in the processing stations.

The robotic arm may be configured to load the respective wafer-shaped articles into each of the three or more processing stations by: moving the first forearm towards the three or more processing stations, with the three or more end effectors in the first arrangement; and moving the three or more end effectors from the first arrangement to the second arrangement, such that each of the three or more end effectors is above an associated one of the three or more processing stations.

Thus, as discussed above, the end effectors can be placed in the first arrangement when the wafer-shaped articles are picked up from the storage unit and as the first forearm is moved towards the three or more processing stations. Then, when the first forearm is in a loading position (e.g. adjacent to the three or more processing stations), the end effectors can be placed in the second arrangement to enable loading of wafer-shaped articles into the processing stations. The three or more end effectors can then be simultaneously lowered (e.g. by lowering the first forearm), in order to load the respective wafer-shaped article into each of the three or more processing stations.

The robotic arm may be configured to pick up the respective wafer-shaped articles with the end effectors in the first arrangement. This may facilitate picking up the wafer-shaped articles and reduce a number of movements required by the robotic arm. This may be achieved by adapting the storage unit to the first arrangement of the end effectors, so that three or more wafer-shaped articles can be simultaneously picked up when the end effectors are in the first arrangement.

An inverse process to that described above may be performed to pick up the wafer-shaped articles from the processing stations and transport them to a storage unit (either the same storage unit the wafer-shaped articles were or a different storage unit). For example, to pick up the wafer-shaped articles from the processing stations, the end effectors may be placed in the second arrangement. Then, once the wafer-shaped articles have been picked up from the processing stations, the end effectors can be put in the first arrangement and the first forearm can be advanced towards the storage unit to load the wafer-shaped articles in the storage unit.

The robotic arm may comprise a plurality of forearms. Each of the three or more processing stations may comprise a rotary chuck having a set of retaining pins for retaining the respective wafer-shaped article; and each rotary chuck may be configured to rotate when the three or more end effectors are moved to the second arrangement, to prevent contact between the set of retaining pins and the associated end effector (to align the set of retaining pins with its associated end effector).

This may serve to ensure that the retaining pins do not interfere with (e.g. contact) the end effectors during loading of the wafer-shaped articles on the processing stations. In particular, the rotary chucks may rotate synchronously with the pivoting or rotating of the end effectors as they are moved to the second arrangement. This may facilitate the procedure of loading the respective wafer-shaped articles into the processing stations.

The retaining pins may be movable, for example rotatable, so as to contact a radially outer edge of the wafer-shaped article when the wafer-shaped article is loaded on the rotary chuck, so as to prevent or restrict lateral movement of the wafer-shaped article relative to the rotary chuck.

The retaining pins may be rotatable gripping pin assemblies.

The retaining pins may also contact an underside of the wafer-shaped article so as to support the wafer-shaped article from beneath, so that the wafer-shaped article is supported spaced apart from a top surface of the rotary chuck.

As an example, each end effector may be configured to support or hold a wafer-shaped article from underneath. For instance, each end effector may comprise a pair of prongs (e.g. a fork) for supporting or holding the wafer-shaped article from underneath. In order to load the wafer-shaped article onto a given rotary chuck, the associated end effector may be lowered towards the rotary chuck. The end effector can then be pulled out from under the wafer-shaped article, with the retaining pins on the rotary chuck serving to retain the wafer-shaped article on the rotary chuck. During this procedure, the rotary chuck may be rotated in synchrony with the movement of the end effector to ensure that the retaining pins do not contact the end effector, such that motion of the end effector is not inhibited by the retaining pins.

The rotation of the rotary chuck may be synchronised with the movement of the end effector both then loading the wafer-shaped article onto the rotary chuck and when picking up the wafer-shaped article from the rotary chuck.

In more general terms, each of the three or more processing stations may comprise a rotary chuck having a set of retaining pins for retaining the respective wafer-shaped article; and each rotary chuck may be configured to rotate when the three or more end effectors are moved to load the respective wafer-shaped articles into the three or more processing stations, to prevent contact between the set of retaining pins and the associated end effector.

Each rotary chuck may be configured to rotate in synchronisation with the movement of the associated end effector.

The three or more processing stations may be arranged at different vertices of a triangle. In other words, the three or more processing stations may be in a triangular arrangement.

This may facilitate loading of the respective wafer-shaped articles into the processing stations. In particular, this may facilitate each end effector being able to simultaneously reach its associated processing station, thus facilitating simultaneous loading, e.g. compared to a situation where the processing stations are arranged in a straight line. For instance, this may enable each end effector to reach its associated processing station when the three or more end effectors are fanned out in the second arrangement discussed above.

The system may further comprise a holding unit configured to hold the storage unit.

The system comprises a plurality of the holding units.

The system may comprise a support configured to support the holding unit.

The system may comprise a plurality of the supports. The robotic arm may be configured or operable to flip the first set of end effectors.

Flipping the first set of end effectors means turning the first set of end effectors upside down, or rotating the first set of end effectors 180 degrees around a longitudinal axis.

In particular, the robotic arm may be configured or operable to flip the first set of end effectors while the first set of end effectors are transporting the wafer-shaped articles, so that the end effectors are above the wafer-shaped articles and support the wafer-shaped articles from above after being flipped.

For example, the end effectors may each comprise a gripping mechanism for gripping the wafer-shaped article, so that the wafer-shaped article is retained by the end effector when the end effector is flipped/turned upside down. For example, each of the end effectors may comprise a plurality of gripping elements such as pins that are configured or operable to grip a radially outer edge of the wafer-shaped article on the end effector.

The robotic arm may be configured to flip the first set of end effectors in order to load the wafer-shaped articles onto the processing stations.

Therefore, the first set of end effectors may be used to support the wafer-shaped articles from above and to lower the wafer-shaped articles onto the respective processing station from above.

For example, the first set of end effectors may each be provided on, or connected to, a first forearm of the robotic arm, and the first forearm may be connected to, or comprise, a pivot joint or rotary joint at which the first forearm can be rotated so as to flip the first set of end effectors.

The first forearm may be rotatable around a longitudinal axis of the first forearm so as to flip the first set of end effectors.

Flipping the first set of end effectors may comprise rotating a common axis around which the first set of end effectors are pivotable by 180 degrees.

With this arrangement, it may not be necessary for a rotary chuck of the processing station to rotate at the same time as, or in synchronisation with, the pivoting of the respective end effector. In particular, since the respective end effector and the robotic arm are positioned above the respective wafer being loaded onto the rotary chuck, there may be no, or a reduced, risk of interference or contact between the robotic arm and retaining pins of the rotary chuck.

The robotic arm may further comprise a second set of end effectors including three or more end effectors; and the robotic arm may be configured to pick up, with each end effector in the second set, a respective wafer-shaped article from each of the three or more processing stations, and load the respective wafer-shaped articles into a storage unit (either the same storage unit that the wafer-shaped articles were removed from or a different storage unit). In this manner, a different set of end effectors may be used for handling pre-processed wafer-shaped articles and wafer-shaped articles which have already been processed. This may avoid cross-contamination between wafer-shaped articles. For example, where the processing stations are used to clean the wafer-shaped articles, this may avoid cross-contamination between dirty (i.e. pre-processed) and clean wafer-shaped articles.

Alternatively, in other embodiments the first set of end effectors may also be used to pick up the wafer-shaped articles from the processing stations and the second set of end effectors may be omitted.

The second set of end effectors may be arranged and operate in a manner analogous to the first set of end effectors discussed above.

The second set of end effectors may have any of the features of the first set of end effectors described above, unless incompatible.

Each end effector in the second set may be associate with a respective one of the processing stations.

Each of the end effectors of the second set may be pivotably mounted about a second common axis, and may be pivotable or rotatable between a first arrangement or configuration and a second arrangement or configuration as discussed above in relation to the first set of end effectors.

The robotic arm may comprise a second forearm, and the three or more end effectors in the second set may be pivotably mounted to the second forearm, the three or more end effectors being pivotable relative to the second forearm about a second common axis. Similarly to the discussion above in relation to the first set of end effectors, making the second set of end effectors pivotable relative to the second forearm may facilitate picking up the respective wafer-shaped articles from the processing stations and transferring them to the storage unit. The inventors have found that providing the first set of end effectors and the second set of end effectors on separate forearms of the robotic arm may facilitate use of the two sets of end effectors for their respective tasks.

The first forearm and the second forearm may both be connected to a main arm portion of the robotic arm. In some cases, the first forearm and the second forearm may both be pivotably connected to the main portion of the robotic arm. This enables each forearm to be pivoted independently of the other, thus increasing a range of relative movement between the two sets of end effectors.

Of course, in an alternative embodiment the first and second sets of end effectors may be pivotably mounted to a same arm or forearm.

The robotic arm may be configured or operable to flip the second set of end effectors. This may be achieved in the same manner described above in relation to the first set of end effectors.

In this case, the second set of end effectors may be positioned above the respective wafer-shaped articles when picking up the respective wafer-shaped articles from the respective processing station.

Once the second set of end effectors have picked up the wafer-shaped articles from the processing stations, the second set of end effectors may then by flipped so that the second set of end effectors are positioned beneath the wafer-shaped articles and support the wafer-shaped articles from beneath. In this configuration, the second set of end effectors can then be used to load the wafer-shaped articles into the storage unit.

This may be achieved by the second set of end effectors each being provided on, or connected to, a second forearm of the robotic arm, and the second forearm may be connected to, or comprise, a pivot joint or rotary joint at which the second forearm can be rotated so as to flip the second set of end effectors.

The second forearm may be rotatable around a longitudinal axis of the second forearm so as to flip the second set of end effectors.

Similarly to the first set of end effectors, the three or more end effectors of the second set may be pivotable relative to the second forearm between a first arrangement (e.g. a transport arrangement) where the three or more end effectors are aligned with one another along the second common axis, and a second arrangement (e.g. a loading arrangement) where the three or more end effectors are at different pivot angles with respect to the second common axis.

The robotic arm may be configured to pick up the respective wafer-shaped articles from the three or more processing stations by putting the three or more end effectors in the second set in the second arrangement, such that each of the three or more end effectors in the second set is above an associated one of the three or more processing stations. The robotic arm may then be configured to put the end effectors of the second set in the first arrangement to transfer the respective wafer-shaped articles to the storage unit.

Where each of the three or more processing stations comprises a rotary chuck having a set of retaining pins for retaining the respective wafer-shaped article; each rotary chuck may be configured to rotate when the three or more end effectors of the second set are moved to the second arrangement, to align the set of retaining pins with its associated end effector in the second set (and/or to prevent contact between the set of retaining pins with its associated end effector).

The robotic arm may be configured to simultaneously pick up the respective wafer-shaped articles with each of the three or more end effectors of the second set from each of the three or more processing stations.

The robotic arm may be configured to simultaneously load the respective wafer-shaped articles into the storage unit.

The system may further comprise a shutter, the shutter being movable between a closed state in which it isolates the robotic arm from the three or more processing stations, and an open state in which is allows the robotic arm to access the three or more processing stations. In this manner, the shutter can be closed during operation of the processing stations, to avoid contamination during processing of the wafer-shaped articles. Advantageously, only a single shutter may be used, as a single robotic arm is used to transfer the wafer-shaped articles between the storage unit and the processing stations. This serves to simplify the system and reduce a number of moving parts.

The three or more processing stations may comprise or be disposed inside a process module, with the shutter being arranged to cover an access opening of the process module when the shutter is closed. Thus, the shutter may be opened in order to enable the robotic arm to access the three or more processing stations. The storage unit may be located outside the process module, i.e. so that the shutter is located between the storage unit and the processing stations when the shutter is closed.

The system may comprise a first set of three or more processing stations and a second set of three or more processing stations, the first set and the second set of three or more processing stations being arranged adjacent to one another.

The robotic arm may be configured to selectively load the respective wafer-shaped articles into the three or more processing stations of the first set or the three or more processing stations of the second set.

In other words, there may be two sets of three or more processing stations next to each other (e.g. side by side), with the robotic arm being capable of loading wafer-shaped articles into either set of processing stations. Thus, a user or the system can select one of the sets of three or more processing stations, and the robotic arm can load the respective wafer-shaped articles into the processing stations of the selected set.

Alternatively, there may be two or more robotic arms, wherein a first robotic arm is configured to load wafer-shaped articles into the first set of processing stations, and a second robotic arm is configured to load wafer-shaped articles into the second set of processing stations.

Where there is more than one robotic arm, each of the robotic arms may be configured to pick up wafer-shaped articles from a storage unit at one or more respective locations.

For example, the system may comprise a plurality of supporting parts for supporting storage units, such as four supporting parts. The first robotic arm may be configured to pick up wafer-shaped articles at a first subset of the supporting parts (for example two of the supporting parts), and the second robotic arm may be configured to pick up wafer-shaped articles at a different second subset of the supporting parts (for example two of the supporting parts).

In sone embodiments, the first robotic arm may be configured or operable to transfer or pass a wafer-shaped article to the second robotic arm. In addition, or alternatively, the second robotic arm may be configured or operable to transfer or pass a wafer-shaped article to the first robotic arm. Such a transfer may be direct, or via an intermediate transfer mechanism.

The first set and the second set of processing stations being adjacent to one another may mean that the first set of processing stations and the second set of processing stations are located side-by-side in substantially a same plane (e.g. a same horizontal plane).

The robotic arm may interact with each set of three or more processing stations as discussed above in relation to the loading of the three or more processing stations. In particular, the robotic arm may be configured to simultaneously load the respective wafer-shaped articles into the processing stations of a selected set of processing stations.

The first set and the second set of processing stations may have a matching layout of processing stations. This may facilitate loading wafer-shaped articles into both sets of processing stations using the same robotic arm. As an example, the first set and the second set of processing stations may be mirror images of one another.

The three or more processing stations in the first set may be configured to operate simultaneously, as discussed above. Likewise, the three or more processing stations of the second set may be configured to operate simultaneously, as discussed above.

The system may comprise a first shutter via which the robotic arm can access the first set of processing stations, and a second shutter, via which the robotic arm can access the second set of processing stations.

The system may be configured to control the robotic arm to alternate between loading wafer-shaped articles into the processing stations of the first set and loading wafer-shaped articles into the processing stations of the second set. In this manner, when the processing stations in the first set are in operation, the robotic arm can load the second set of processing stations (and vice versa). This may serve to increase a throughput of the system.

The system may comprise two or more levels arranged one above another, wherein each level comprises a respective set of three or more processing stations, wherein the robotic arm is configured to selectively load the respective wafer-shaped articles into the set of three or more processing stations of one of the two or more levels. In other words, there may be multiple sets of processing stations which are stacked one above the other, with the robotic arm being capable of loading wafer-shaped articles into any of the sets of processing stations. Thus, a user or the system can select one of the sets of three or more processing stations, and the robotic arm can load the respective wafer-shaped articles into the processing stations of the selected set.

The robotic arm may be mounted on or attached to, for example pivotably mounted on or pivotably attached to, a turret that is configured to move in a vertical direction so as to move the robotic arm between the two or more levels.

The robotic arm may interact with the set(s) of processing stations in each level as discussed above in relation to the loading of the three or more processing stations. In particular, the robotic arm may be configured to simultaneously load the respective wafer-shaped articles into the processing stations of a selected set of processing stations.

The sets of processing stations arranged at different levels may have a matching layout of processing stations. This may facilitate loading wafer-shaped articles into both sets of processing stations using the same robotic arm. As an example, each level may comprise a same spatial arrangement of processing stations.

In some cases, each level may comprise a first set of three or more processing stations, and a second set of three or more processing stations adjacent to one another, as discussed above.

The system may further comprise an actuator for controlling a height of the robotic arm in the system. This may facilitate picking up wafer-shaped articles and loading them into the processing stations, as the picking up and loading may involve raising and/or lowering the end effectors. Where the system comprises two or more levels with processing stations, this may also enable the robotic arm to reach the different levels.

The actuator may comprise any suitable type of actuator for controlling a height of the robotic arm. As an example, the actuator may comprise a belt driven actuator, an elevator system, and/or a pulley system. As mentioned above, the actuator may comprise a turret that is configured to move in a vertical direction.

Herein, sets of three or more processing stations and sets of three or more end effectors are discussed. In general, the number of end effectors in a set may correspond to the number of processing stations in a set, so that each end effector can be associated with a respective processing station.

For example, the system may comprise N processing stations and the first set of end effectors may include N end effectors, where N is a number equal to 3 or more than 3. The system may comprise only or exactly N processing stations, and the first set of end effectors may comprise only or exactly N end effectors.

Where present, the second set of end effectors may also comprise only or exactly N end effectors.

N may be equal to 3.

According to a second aspect of the invention, there is provided a method for processing wafer-shaped articles, the method comprising: using a robotic arm comprising a first set of end effectors including three or more end effectors, picking up from a storage unit a respective wafer-shaped article with each of the three or more end effectors; loading, with the robotic arm, one of the respective wafer-shaped articles into each of three or more processing stations.

The method of the second aspect of the invention may be used with the system of the first aspect of the invention. Accordingly, any features discussed above in relation to the first aspect of the invention may be shared with the second aspect of the invention.

The respective wafer-shaped articles may be simultaneously loaded into each of the three or more processing stations.

The respective wafer-shaped articles are simultaneously picked up with each of the three or more end effectors.

The method may further comprise: following the loading of the respective wafer-shaped articles into each of the three or more processing stations, operating the three or more processing stations to process the respective wafer-shaped articles.

The method may comprise simultaneously operating the three or more processing stations to process the respective wafer-shaped articles.

The robotic arm may further comprise a second set of end effectors including three or more end effectors, and the method may further comprise: following the processing of the respective wafer-shaped articles, picking up, with each end effector in the second set, one of the respective wafer-shaped articles from one of the three or more processing stations; and loading the respective wafer-shaped articles into a storage unit (which may be the same storage unit that the wafers were removed from or a different storage unit).

Used herein the term fluid may mean a liquid, and any references to fluid herein can be replaced with the term liquid, unless incompatible.

According to a third aspect of the present invention there is provided a robotic arm comprising a first set of end effectors including three or more end effectors;
wherein the robotic arm is configured to pick up, from a storage unit configured to store a plurality of wafer-shaped articles, a respective wafer-shaped article with each of the three or more end effectors, and load one of the respective wafer-shaped articles into each of three or more processing stations.

The robotic arm according to the third aspect of the present invention may have any of the features of the robotic arm according to the first or second aspects of the present invention.

For example, the first set of end effectors according to the third aspect of the present invention may have any of the features of the first set of end effectors according to the first or second aspects of the present invention.

The robotic arm may be configured to flip the first set of effectors. This may be achieved in the same manner as in the first or second aspects of the present invention described above.

According to a fourth aspect of the present invention there is provided a robotic arm comprising a first set of end effectors including three or more end effectors, wherein each of the three or more end effectors is pivotably mounted about a first common axis.

The robotic arm according to the fourth aspect of the present invention may have any of the features of the robotic arm according to the first to third aspects of the present invention.

For example, the first set of end effectors according to the fourth aspect of the present invention may have any of the features of the first set of end effectors according to the first to third aspects of the present invention.

The three or more end effectors may be pivotable to a first configuration in which the three or more end effectors are aligned along the first common axis, and/or overlap along the first common axis.

The three or more end effectors may be pivotable to a second configuration in which the three or more end effectors are fanned-out.

### BRIEF DESCRIPTION OF THE DRAWINGS

Embodiments of the present invention will now be discussed, by way of example only, with reference to the accompanying Figures, in which:

FIG. 1 is a schematic diagram showing a top view of a system according to an embodiment of the invention;

FIG. 2a is a schematic diagram showing a top view of a robotic arm of the system of FIG. 1, where end effectors of the robotic arm are in a loading arrangement;

FIG. 2b is a schematic diagram showing a top view of the robotic arm of the system of FIG. 1, where the end effectors of the robotic arm are in a transport arrangement;

FIG. 3a is a schematic diagram showing a cross-sectional view of part of the robotic arm of the system of FIG. 1, where the end effectors of the robotic arm are in the transport arrangement; FIG. 3b is a schematic diagram showing a cross-sectional view of part of the robotic arm of the system of FIG. 1, where the end effectors of the robotic arm are in the transport arrangement, and where each end effector is carrying a respective wafer-shaped article; FIGS. 4a and 4b are schematic diagrams showing top views of part of the system of FIG. 1, illustrating a process of loading a wafer onto a rotary chuck;

FIG. 5 is a schematic diagram showing a cross-sectional side view of a particular embodiment of the system of FIG. 1;

FIG. 6 is a schematic diagram showing a perspective view of a robotic arm that may be part of a system according to an embodiment of the invention;

FIGS. 7a and 7b are schematic diagrams showing alternative configurations of the robotic arm of FIG. 6;

FIG. 8 is a schematic diagram showing a perspective view of a robotic arm that may be part of a system according to an embodiment of the invention;

FIG. 9 is a schematic diagram of a fluid supply system that may be part of a system according to an embodiment of the invention;

FIG. 10 is a schematic diagram of a fluid supply system that may be part of a system according to an embodiment of the invention, and

FIG. 11 is a schematic diagram of a fluid supply system that may be part of a system according to an embodiment of the invention.

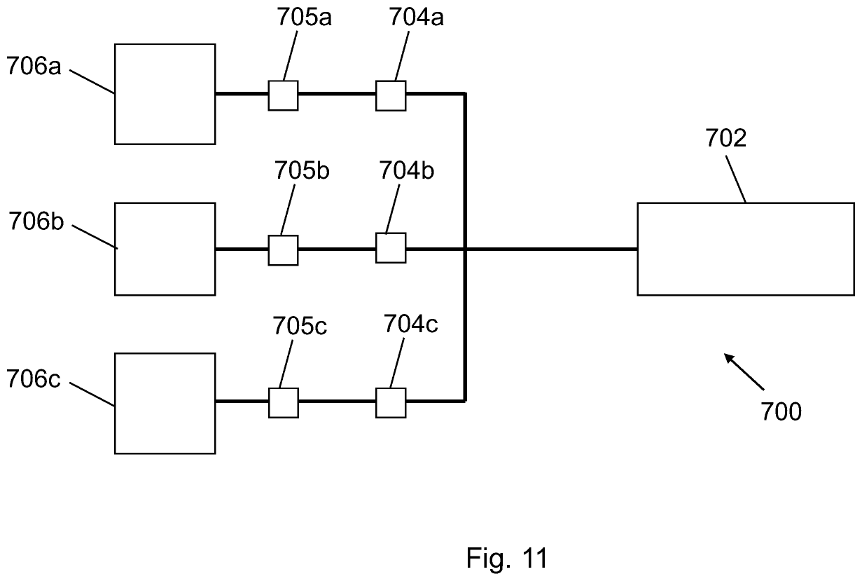

### DETAILED DESCRIPTION OF THE PREFERRED EMBODIMENTS AND FURTHER OPTIONAL FEATURES OF THE INVENTION

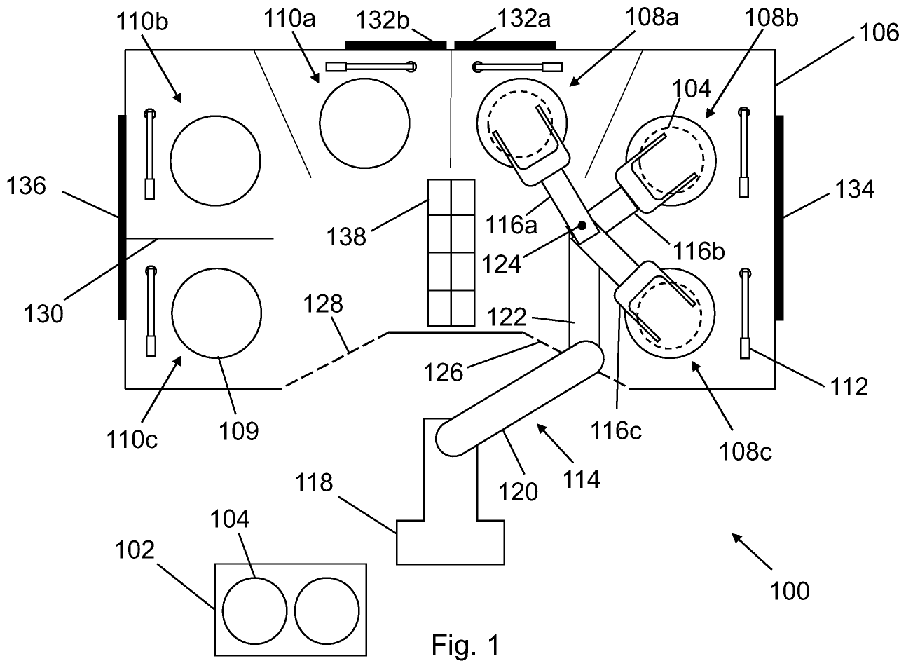

FIG. 1 shows a schematic diagram of a system 100 according to an embodiment of the invention. The schematic diagram of FIG. 1 represents a top view of the system 100. Thus, the plane of the page in FIG. 1 may correspond to a substantially horizontal plane. The system 100 is configured to process wafer-shaped articles, such as semiconductor wafers. For convenience, the detailed description will refer to ‘wafers’, however it should be understood that the term ‘wafer’ may refer to any wafer-shaped article.

The system 100 comprises a storage unit 102 configured to store a plurality of wafers 104. In one example, the storage unit 102 may store the plurality of wafers 104 in one or more stacks, which may facilitate retrieving wafers from, and storing wafers in, the storage unit 102. For instance, the storage unit may comprise a plurality of shelves arranged one above the other, each for receiving a respective wafer 104. The storage unit 102 may be a container or a cassette, for example a FOUP.

The storage unit 102 may be transported to the system 100 from another apparatus and/or from another location in a processing or fabrication environment.

The system 100 may comprise a holding unit for receiving and holding the storage unit 102. The system 100 may comprise a plurality of such holding units. The system 100 may therefore be able to receive a plurality of the storage units 102 at the same time.

The system 100 further comprises a process module 106 in which two sets of wafer processing stations are located. In more detail, a first set of three processing stations 108a, 108b, 108c is located on a first side of the process module 106, and a second set of three processing stations 110a, 110b, 110c is located on a second side of the process module 106. Each wafer processing station in the first set and the second set is configured to process an individual wafer. Examples of processes that the wafer processing stations may be configured to perform include etching and/or cleaning processes, and bevel etch processes, for example. The wafer processing stations 108a, 108b, 108c are all configured to perform a same process, and likewise the wafer processing stations 110a, 110b, 110c in the second set are all configured to perform a same process. The processes performed by the first set and the second set may be the same or different processes. The wafer processing stations 108a, 108b, 108c in the first set may be referred to as a first triplet, and the wafer processing stations 110a, 110b, 110c in the second set may be referred to as a second triplet.

Each wafer processing station in the first set and the second set comprises a rotary chuck 109 (or spin chuck), which is configured to receive a wafer and spin the wafer. The rotary chucks 109 may be any suitable type of rotary chuck, and their size may be adapted to the wafers which are to be processed. Each rotary chuck 109 may include a mechanism for holding a wafer in place on the rotary chuck 109, such as a set of retaining pins and/or suction ports for retaining the wafer by applying suction to it.

Additionally, a fluid dispenser 112 is provided for each wafer processing station, the fluid dispenser 112 being configured to dispense fluid onto a wafer that is received on the rotary chuck 109. The fluid dispenser 112 is on a pivotable arm, so that it can be pivoted between a dispensing position where it is arranged above the rotary chuck 109 to dispense fluid onto the wafer received on the rotary chuck 109, and an idle position where it is pivoted away from the rotary chuck 109 (in FIG. 1, all the fluid dispensers 112 are shown in the idle position). The fluid dispenser 112 of each wafer processing station may be connected to a fluid source (not shown), which may include a cleaning fluid, a rinsing fluid, an etching fluid, or another type of processing fluid or chemical. In some cases, multiple fluid dispensers may be provided for each wafer processing station, each fluid dispenser being arranged to dispense a different fluid onto a wafer received on the rotary chuck 109 (e.g. each fluid dispenser may be connected to a different fluid source).

The fluid dispenser 112 may be a liquid dispenser for dispensing a liquid onto a wafer that is received on the rotary chuck.

Each wafer processing station may comprise two or more of the fluid dispensers 112. For example, each of the processing stations may comprise a first fluid dispenser for dispensing a first fluid, such as an acid or an etching or cleaning fluid. In addition, each of the processing stations may comprise a second fluid dispenser for dispensing a rinsing fluid, such as deionised water. The second fluid dispenser may also be for dispensing a gas such as Nitrogen for drying the wafer.

The system 100 further comprises a robotic arm 114. The robotic arm 114 is configured to transfer wafers 104 between a single storage unit 102 and the wafer processing stations in the process module 106. The robotic arm 114 comprises a first set of three end effectors 116ₐ, 116_{b}, 116_{c}, each of which is configured to hold a respective wafer. In the example shown, the end effectors 116a, 116b, 116c each have a pair of jaws (or a fork or pair or prongs) which is arranged to hold an individual wafer. The jaws may be stationary or movable relative to one another, as required. The jaws of each end effector may comprise a retaining mechanism (e.g. a gripper or clamp) for holding the wafer on the jaws during transport of the wafer between the storage unit 102 and the wafer processing stations. Additionally, or alternatively, the jaws of each end effector may include one of more suction ports, for applying suction to a wafer disposed on the jaws, in order to hold the wafer on the jaws during transport of the wafer between the storage unit 102 and the wafer processing stations. Alternatively, or in addition, the jaws of each end effector may be configured to support the wafer by contacting the wafer from beneath.

The robotic arm 114 is configured to pick up a respective wafer from the single storage unit 102 with each of the end effectors 116a, 116b, 116c. The robotic arm can then load the picked up wafers into the wafer processing stations of the first set or the second set. In FIG. 1, the robotic arm 114 is shown in a position where the end effectors 116a, 116b, 116c are above the wafer processing stations 108a, 108b, 108c of the first set, such that the robotic arm 114 is arranged to load wafers into the wafer processing stations 108a, 108b, 108c of the first set. Each end effector 116a, 116b, 116c may be associated with a respective wafer processing station in the first set and the second set. In the example shown, the end effectors 116a, 116b, 116c are associated with the wafer processing stations 108a, 108b, 108c in the first set, respectively. Likewise, the end effectors 116a, 116b, 116c are associated with the wafer processing stations 110a, 110b, 110c in the second set, respectively. Thus, the associated end effector may be used by the robotic arm 114 to load a wafer into a given wafer processing station in the first set or the second set.

Of course, in other embodiments separate robotic arms 114 may be provided for each of the first and second sets of wafer processing stations, instead of a single robotic arm for both sets.

The robotic arm 114 may include multiple articulated members (or arms), to enable it to move between the storage unit 102 and the wafer processing stations. The specific structure of the robotic arm 114 may be adapted to the spatial arrangements of the storage unit 102, process module 106 and wafer processing stations. In the example shown, the robotic arm 114 includes a turret 118 (or base portion), to which an upper arm 120 (or intermediate arm) is pivotably connected. A first forearm 122 is pivotably connected to the upper arm 120. The end effectors 116a, 116b, 116c are all pivotably connected to a working end (or distal end) of the first forearm 122, the end effectors 116a, 116b, 116c being pivotable relative to the first forearm about a first common axis. For example, each of the end effectors 116a, 116b, 116c may be pivotably connected to a pivot axle 124 located at the working end (or distal end) of the first forearm 122. The first common axis may be substantially vertical, i.e. the pivot axle 124 may extend in a substantially vertical direction. The robotic arm 114 may include any suitable arrangement of motors and/or actuators for controlling movements of its different parts.

The end effectors 116a, 116b, 116c are arranged one above another in the vertical direction, i.e. along the pivot axle 124. Spaces are provided between the end effectors 116a, 116b, 116c in the vertical direction so that the end effectors 116a, 116b, 116c can each pick up a respective wafer.

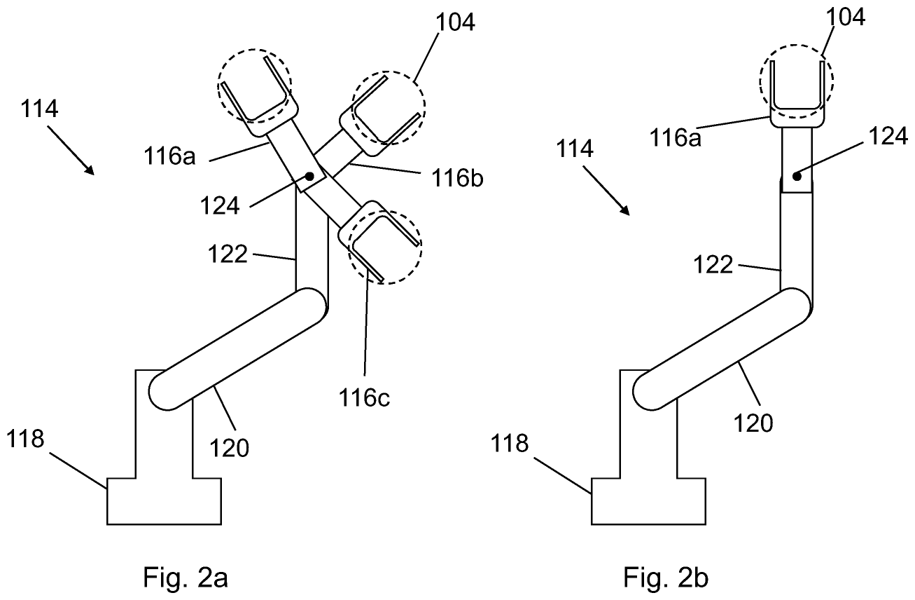

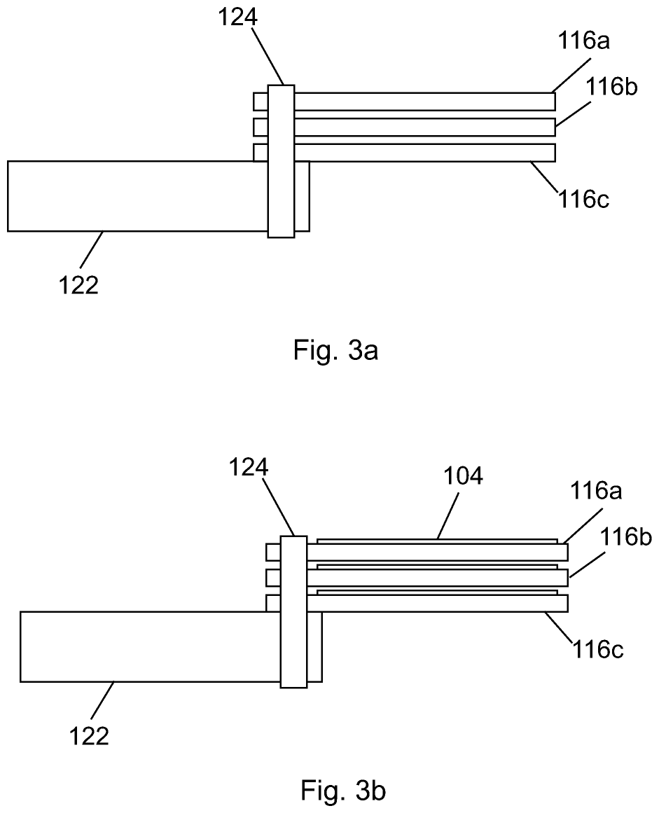

The robotic arm 114 is depicted on its own in FIGS. 2a and 2b. The end effectors 116a, 116b, 116c are pivotable relative to the first forearm 122 between a transport arrangement and a loading arrangement. The dashed lines in FIGS. 2a and 2b depict where the end effectors 116a, 116b, 116c would hold the wafers 104. The loading arrangement of the end effectors 116a, 116b, 116c is depicted in FIGS. 1 and 2a. As can be seen, in the loading arrangement, the end effectors 116a, 116b, 116c are at different pivot angles with respect to the first common axis, such that they are fanned out about the pivot axle 124. With the end effectors 116a, 116b, 116c in the loading arrangement, the robotic arm 114 can position the end effectors 116a, 116b, 116c such that each end effector is located above its associated wafer processing station in one of the sets of wafer processing stations. For example, in the arrangement shown in FIG. 1, each end effector is located above its associated wafer processing station in the first set.

As can be seen in FIG. 1, the wafer processing stations 108a, 108b, 108c in the first set are in a triangular arrangement, i.e. each wafer processing station in the first set is located at the vertex of a triangle. This enables each end effector to be positioned above its associated wafer processing station in the first set by pivoting the end effectors 108a, 108b, 108c about the pivot axle 124. For example, the wafer processing stations 108a, 108b, 108c lie on an arc, to facilitate reaching them with the pivoting motions of the end effectors 116a, 116b, 116c. The wafer processing stations 110a, 110b, 110c in the second set may have an arrangement matching that of the first set, to similarly enable each end effector to be positioned above its associated wafer processing station in the second set. The arrangement of the wafer processing stations 110a, 110b, 110c in the second set may correspond to a mirror image of the arrangement of the wafer processing stations 108a, 108b, 108c, as shown in FIG. 1.

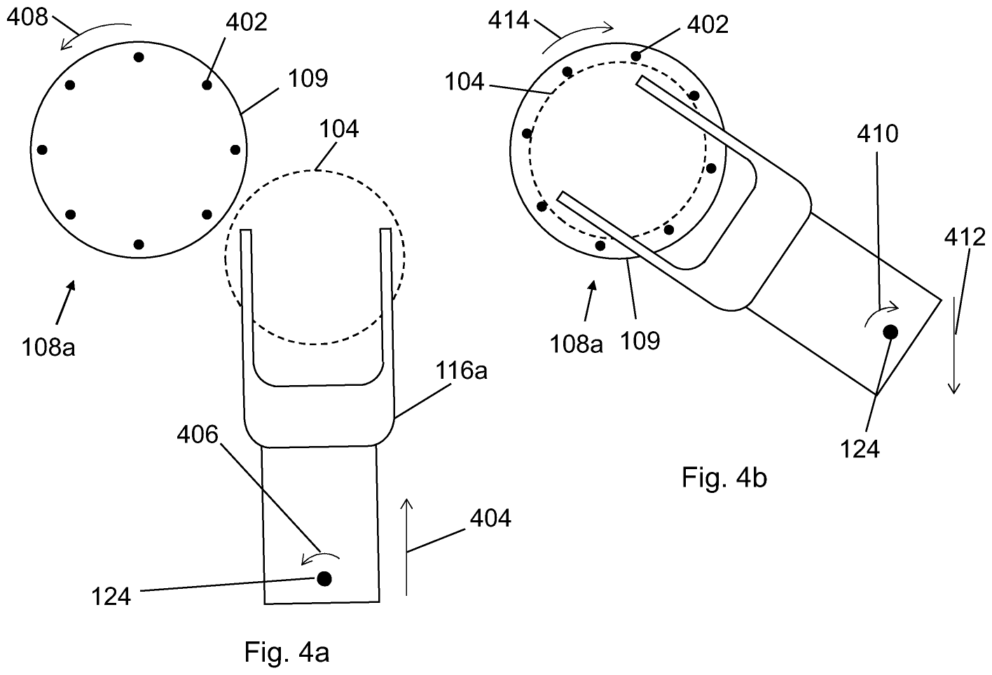

The transport arrangement of the end effectors 116a, 116b, 116c is shown in FIG. 2b. In the transport arrangement, the end effectors 116a, 116b, 116c are all aligned with one another along the first common axis, i.e. the end effectors 116a, 116b, 116c are all at a same pivot angle with respect to the pivot axle 124. Accordingly, only the topmost end effector 116a can be seen in the top view of FIG. 2b. FIGS. 3a and 3b are schematic diagrams of a cross-sectional view of a portion of the robotic arm 114, where the end effectors 116a, 116b, 116c are in the transport arrangement. As can be seen in FIGS. 3a and 3b, each the end effectors 116a, 116b, 116c is connected to the pivot axle 124, with the end effectors 116a, 116b, 116c being arranged one above the other along the pivot axle 124. In FIG. 3a, the end effectors 116a, 116b, 116c are not carrying any wafers, whilst in FIG. 3b each of the end effectors 116a, 116b, 116c is shown as carrying a respective wafer 104. As can be seen, the end effectors 116a, 116b, 116care spaced along the vertical axle, to enable each end effector to carry a respective wafer when the end effectors 116a, 116b, 116c are in the transport arrangement.

The robotic arm 114 may be configured to put the end effectors 116a, 116b, 116c in the transport arrangement when transferring wafers between the storage unit 102 and the wafer processing stations. Advantageously, the transport arrangement of the end effectors 116a, 116b, 116c is more compact (e.g. compared to the loading arrangement), thus facilitating moving the robotic arm 114 between the storage unit 102 and the wafer processing stations. Additionally, the robotic arm 114 may be configured to pick up wafers 104 from the storage unit 102 with the end effectors 116a, 116b, 116c in the transport arrangement. In particular, where the storage unit 102 stores a plurality of wafers 104 in a vertical stack as mentioned above, the robotic arm 114 may lift a stack of three wafers out of the storage unit 102 using the end effectors 116a, 116b, 116c in the transport arrangement. In this manner, the robotic arm 114 can simultaneously pick up three wafers 104 from the single storage unit 102. For example, a vertical spacing of wafer-carrying shelves in the storage unit 102 may be arranged to match the vertical spacing between the end effectors 116a, 116b, 116c along the pivot axle 124, so that the end effectors 116a, 116b, 116c can be inserted into the storage unit 102 in the transport arrangement to lift out three wafers 104.

The turret 118 of the robotic arm 114 may include or be mounted on an actuator for controlling a height of the robotic arm 114 (and hence the end effectors 116a, 116b, 116c) in the system 100. For example, this may enable the end effectors 116a, 116b, 116c to be raised and lowered, e.g. in order to pick up wafers 104 from the storage unit 102 and to load wafers 104 onto the wafer processing stations. In particular, picking up wafers 104 from the storage unit 102 may comprise raising the end effectors 116a, 116b, 116c, to lift the wafers 104 out of the storage unit 102. Loading wafers 104 onto the wafer processing stations may comprise lowering the end effectors 116a, 116b, 116c to place the wafers on the wafer processing stations.

The process module 106 may comprise a first shutter 126 and a second shutter 128. The first shutter 126 and the second shutter 128 can be closed to isolate the robotic arm 114 from an inside of the process module 106. The first shutter 126 can be opened to enable the robotic arm 114 to access the first set of wafer processing stations 108a, 108b, 108c. Likewise, the second shutter 128 can be opened to enable the robotic arm to access the second set of wafer processing stations 110a, 110b, 110c. The dashed lines indicated by reference numerals 126 and 128 in FIG. 1 indicate the positions of the first shutter 126 and the second shutter 128 when these are closed.

The process module 106 may further comprise separation walls 130 located between adjacent wafer processing stations in the process module 106. The separations walls 130 serve to prevent cross-contamination between the different wafer processing stations. For example, the separation walls 130 may act as splash barriers, to prevent fluids from being splashed or otherwise transmitted between adjacent wafer processing stations. FIG. 1 also shows a set of exhaust outlets 138 located in the process module 106 between the first set and the second set of wafer processing stations. The exhaust outlets 138 may serve to extract fumes from inside the process module 106.

In addition, a wall may also be provided in the process module 106 between the first set of wafer processing stations 108a, 108b, 108c and the second set of wafer processing stations 110a, 110b, 110c. For example, the wall may be along a middle of the process module 106. The wall may isolate the first set of wafer processing stations 108a, 108b, 108c from the second set of wafer processing stations 110a, 110b, 110c. This may enable maintenance to be performed on one of the sets of wafer processing stations while still allowing use of the other set of wafer processing stations, for example.

The process module 106 may further comprise one or more service doors, for accessing an inside of the process module 106, e.g. to perform maintenance on the wafer processing stations. In the example shown, the process module 106 includes a first service door 132a arranged to provide access to wafer processing station 108a, a second service door 132b arranged to provide access to wafer processing station 110a, a third service door 134 arranged to provide access to wafer processing stations 108b and 108c, and a fourth service door 136 arranged to provide access to wafer processing stations 110b and 110c.

The system 100 may comprise a controller (not shown) configured to control operation of the various parts of the system 100. In particular, the controller may control movements of the robotic arm 114 for controlling transfer of wafers 104 between the storage unit 102 and the wafer processing stations. The controller may also control operation of the wafer processing stations, to control processes performed by the wafer processing stations. The controller may comprise any suitable computing system or collection of computing systems capable of controlling operation of the system 100. Additionally or alternatively, the system 100 may be controllable by a user. For example, the system 100 may comprise a user interface for controlling movements of the robotic arm 114 and/or operation of the wafer processing stations.

In use, the robotic arm 114 may initially pick up three wafers 104 from the single storage unit 102, one with each end effector 116a, 116b, 116c. As discussed above, this may be achieved by putting the end effectors 116a, 116b, 116c in the transport arrangement, and lifting out three wafers 104 from a stack of wafers stored in the storage unit 102. Depending on which set of wafer processing stations is to be loaded with the wafers, the robotic arm 114 may then move the end effectors 116a, 116b, 116c towards the first or the second set of wafer processing stations. For the sake of example, loading of wafers into the first set of wafer processing stations will be described, however the described steps are equally applicable for the second set of wafer processing stations.

Following picking up of the wafers with the end effectors 116a, 116b, 116c, the robotic arm 114 may then move the end effectors 116a, 116b, 116c in the transport arrangement towards the first set of wafer processing stations 108a, 108b, 108c. This may be achieved by opening the first shutter 126 and advancing the first forearm 122 (and hence the end effectors 116a, 116b, 116c) into the process module towards the first set of wafer processing stations 108a, 108b, 108c. The end effectors 116a, 116b, 116c may then be pivoted to put them in the loading arrangement, such that each end effector is positioned above its associated wafer processing station in the first set as shown in FIG. 1. In this position, the robotic arm 114 can lower the end effectors 116a, 116b, 116c, to place the wafers on the rotary chucks 109 of the wafer processing stations 108a, 108b, 108c. The robotic arm 114 may then withdraw the end effectors 116a, 116b, 116c from wafer processing stations, leaving the wafers 104 in place on the wafer processing stations. For example, retaining elements on the rotary chucks 109, such as retaining pins, may act to hold the wafers 104 on the rotary chucks 109 as the end effectors 116a, 116b, 116c are withdrawn. Accordingly, the robotic arm 114 can simultaneously load a respective wafer 104 onto each of the wafer processing stations 108a, 108b, 108c in the first set. Analogously, the robotic arm 114 can simultaneously load a respective wafer 104 onto each of the wafer processing stations 110a, 110b, 110c in the second set.

Following the loading of the wafers 104 into the wafer processing stations 108a, 108b, 108c in the first set, the end effectors 116a, 116b, 116c may be returned to the transport arrangement, and the robotic arm 114 can withdraw from the process module 106. Subsequently, the first shutter 126 can be closed, and the wafer processing stations 108a, 108b, 108c can be operated simultaneously to simultaneously process the wafers 104. For example, the fluid dispensers 112 may dispense a fluid onto a surface of the wafers and spin the wafers with the rotary chucks 109.

Whilst the wafer processing stations 108a, 108b, 108c in the first set are being operated to process the wafers 104, the robotic arm can at the same time load wafers 104 from the storage unit 102 into the wafer processing stations 110a, 110b, 110c of the second set. An analogous set of steps to those discussed above may be performed for loading wafers 104 into the wafer processing stations 110a, 110b, 110c of the second set.

Following the processing of the wafers 104 by the wafer processing stations 108a, 108b, 108c in the first set, the robotic arm 114 can retrieve the wafers 104 and return them to a storage unit 102 (either the same storage unit that the wafers 104 were removed from or a different storage unit). Specifically, the first shutter 126 can be opened, so that the robotic arm 114 can advance the end effectors 116a, 116b, 116c in the transport arrangement into the process module 106 towards the first set of wafer processing stations. The end effectors 116a, 116b, 116c can then be pivoted to the loading arrangement (e.g. as shown in FIG. 1), so that each end effector can pick up the wafer 104 from its associated wafer processing station in the first set. The robotic arm 114 can then place the end effectors 116a, 116b, 116c in the transport arrangement, to transport the wafers to the storage unit 102. Keeping the end effectors 116a, 116b, 116c in the transport arrangement, the robotic arm 114 can load the wafers into the storage unit, e.g. by lowering the wafers 104 onto shelves in the storage unit 102. The storage unit 102 may comprise a first portion for storing pre-processed wafers 104, and a second portion for storing processed wafers 104. In such a case, the wafers 104 picked up from the first set of wafer processing stations can be loaded into the second portion of the storage unit 102. Analogously, the robotic arm 114 can, following the processing of wafers 104 by the second set of wafer processing stations, pick up the wafers 104 from the second set of wafer processing stations and load them into the storage unit 102.

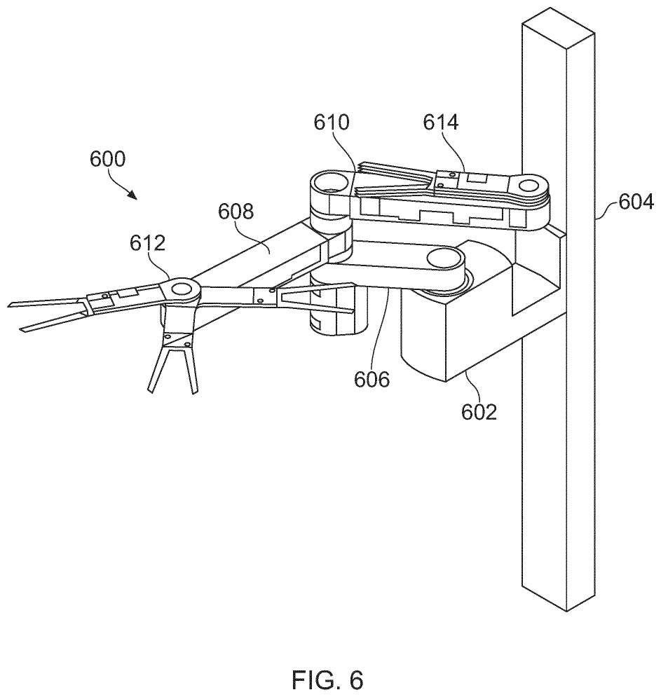

In the above example, the same set of end effectors 116a, 116b, 116c is used to transfer wafers 104 from the storage unit 102 to the wafer processing stations, and from the wafer processing stations to the storage unit 102. However, in other examples, the robotic arm 114 may comprise a second set of end effectors, such that a different set of end effectors can be used for each direction of wafer transfer. An example of a robotic arm with two sets of end effectors is described below, in relation to FIG. 6.

FIGS. 4a and 4b illustrate in more detail an example of movements performed during loading of a wafer 104 onto the rotary chuck 109 of one of the wafer processing stations of the system 100. FIGS. 4a and 4b are top views of showing only a part of the system 100. In particular, only the end effector 116a and the rotary chuck 109 in its associated wafer processing station 108a in the first set are shown.

As can be seen in FIGS. 4a and 4b, the rotary chuck 109 of the wafer processing station 108a includes a set of retaining pins 402 arranged around its edge. The retaining pins 402 extend vertically from a surface of the rotary chuck 109, and are arranged to retain a wafer 104 on the rotary chuck 109 when the wafer 104 is placed on the rotary chuck 109. The rotary chuck 109 of each wafer processing station in the system 100 may include an equivalent set of retaining pins.

The retaining pins may be movable, for example rotatable, so as to contact a radially outer edge of the wafer 104 on the rotary chuck 109 so as to prevent or restrain lateral movement of the wafer 104 relative to the surface of the rotary chuck 109.

The dashed lines in FIGS. 4a and 4b indicate the position of a wafer 104 held by the end effector 116a. In order to position the end effector 116a over the rotary chuck 109 of the wafer processing station 108a, the robotic arm 114 advances the first forearm 122 towards the first set of wafer processing stations, along the direction indicated by arrow 404 in FIG. 4a. At the same time, the end effector 116a is pivoted about the axle 124 as shown by arrow 406 in FIG. 4a, in order to align the end effector 116a over the rotary chuck 109. The pivoting of the end effector 116a may be part of moving the end effectors 116a, 116b, 116c from the transport arrangement to the loading arrangement. This results in the end effector 116a (and the wafer 104 that it is carrying) to be positioned over the rotary chuck 109. To load the wafer 104 onto the rotary chuck 109, the robotic arm 114 can then lower the end effector 116a towards the rotary chuck 109.

In order to avoid the retaining pins 402 interfering with movement of the end effector 116a when the end effector 116a is lowered towards the rotary chuck 109, the rotary chuck 109 can be rotated as shown by arrow 408 in FIG. 4a. In this manner, the retaining pins 402 can be moved out of the way of the end effector 116a. In particular, the rotary chuck 109 can be rotated to ensure that none of the retaining pins 402 are located directly below the end effector 116a when the end effector 116a is positioned above the rotary chuck 109. The direction of rotation of the rotary chuck 109 during loading of the wafer 104 may correspond to the direction (i.e. be the same direction) in which the end effector 116a is pivoted. In the example shown in FIG. 4a, the rotary chuck 109 rotates, and the end effector 116a pivots, in a counter-clockwise direction. Alternatively, the direction of rotation of the rotary chuck 109 during loading of the wafer 104 may be in an opposite direction to the direction in which the end effector 116a is pivoted. The rotary chuck 109 may be configured to rotate synchronously with the pivoting of the end effector 116a. Alternatively, the rotary chuck 109 can be rotated before or after pivoting of the end effector 116a.

Once the end effector 116a is positioned over the rotary chuck 109 as shown in FIG. 4b, the robotic arm 114 can lower the end effector 116 towards the rotary chuck 109. When the end effector 116a is lowered towards the rotary chuck 109, the retaining pins 402 may engage an outer edge of the wafer 104. The end effector 116a can then be pulled out from underneath the wafer 104, with the wafer 104 being retained on the rotary chuck 109 by the retaining pins 402. In some cases, the wafer 104 may be held spaced apart from a surface of the rotary chuck 109, e.g. by a cushion of gas, or by the retaining pins, or further pins located on the surface of the rotary chuck 109, contacting an underside of the wafer to support the wafer 104.

Of course, the end effector may be lowered simultaneously with pivoting of the end effector, rather than as separate steps.

Withdrawing the end effector 116a from underneath the wafer 104 may involve pivoting the end effector 116a as shown by arrow 410 in FIG. 4b, e.g. in an opposite direction to the pivoting indicated by arrow 406. At the same time, the robotic arm 114 may retract the first forearm 122 away from the wafer processing stations in the first set, e.g. along the direction shown by arrow 412 in FIG. 4b. To avoid the retaining pins 402 interfering with the end effector 116a whilst the end effector 116a is withdrawn from the rotary chuck 109, the rotary chuck 109 can be rotated in synchrony with the pivoting of the rotary chuck 109 to avoid collisions between the retaining pins 402 and the end effector 116a. In particular, the rotary chuck 109 can be rotated as indicated by arrow 414 in FIG. 4b, during withdrawal of the end effector 116a. The direction of rotation of the rotary chuck is the same as the direction of pivoting of the end effector 116a. In the example shown in FIG. 4b, the rotary chuck 109 rotates, and the end effector 116a pivots, in a clockwise direction. Alternatively, the direction of rotation of the rotary chuck during withdrawal of the end effector 116a may be in an opposite direction to the direction of pivoting of the end effector 116a during withdrawal of the end effector 116a.

Each of the retaining pins 402 may be rotatable between a first position in which it is configured to exert a clamping force on the radially outer edge of the wafer 104, and a second position in which it does not exert the clamping force on the wafer 104. This may be achieved, for example, by providing the retaining pins 402 with a non-circular cross-section. When the wafer 104 is lowered onto the rotary chuck 109, the retaining pins 402 may be in the second position, to allow the wafer 104 to be lowered onto the rotary chuck 109. Then, the retaining pins 402 may be rotated to the first position to exert a clamping force on the wafer 104, to securely hold the wafer 104 on the rotary chuck 109. This may enable the wafer 104 to be held by the retaining pins 402 above an upper surface of the rotary chuck 109, e.g. so that there is a gap between the wafer 104 and the upper surface of the rotary chuck 109.

A similar procedure to that described above in relation to FIGS. 4a and 4b may be used to subsequently pick up the wafer 104 from the rotary chuck 109. In particular, the robotic arm 114 may insert the end effector 116 under the wafer 104 in order to lift the wafer 104 away from the rotary chuck. This may involve a similar sequence of pivoting and rotational movements to that described above.

Analogous movements to those discussed above for the end effector 116a and the rotary chuck of the wafer processing station 108a may be performed by the other end effectors and the rotary chucks of their associated wafer processing stations, in order to load wafers into all of the wafer processing stations of the first set or the second set.

As discussed above, in an alternative arrangement the robotic arm may be configured to flip the end effectors, for example by rotating the first forearm around a longitudinal axis of the first forearm, so that the end effectors support the wafers from above when the end effectors are used to lower the wafers onto the wafer processing stations.

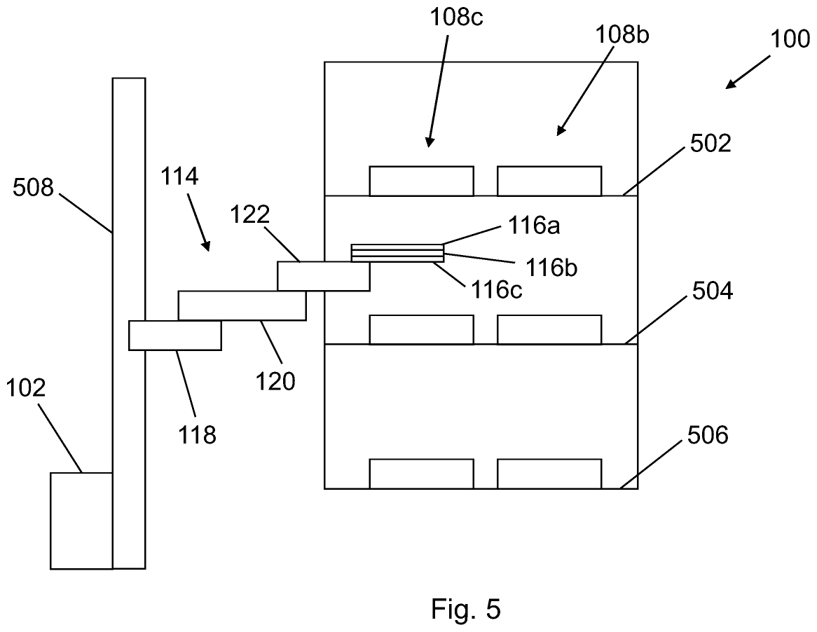

FIG. 5 shows a schematic cross-sectional side view of a particular embodiment of the system 100. In this embodiment, the system 100 includes three levels 502, 504, 506, with two sets of three wafer processing stations being arranged in each level. The sets of wafer processing stations in each level are arranged as shown in FIG. 1. In the view of FIG. 5, only two wafer processing stations are visible at each level, however each level includes six wafer processing stations as shown in FIG. 1. Thus, the system 100 of FIG. 5 includes a total of eighteen wafer processing stations.

As shown in FIG. 5, the system 100 includes an actuator 508 for controlling a height of the robotic arm 114 in the system 100. Specifically, the turret 118 of the robotic arm 118 is connected to the actuator 508. As an example, the actuator 508 may comprise a belt drive configured to adjust a height of the robotic arm 114. Other types of actuators 508 may also be used, such as a pulley system or an elevator system. Using the actuator 508, the robotic arm 114 can be raised and lowered, in order to enable it to transfer wafers 104 between the storage unit 102 and the wafer processing stations in each of the levels 502, 504, 506. The actuator 508 may also be used to control the height of the end effectors 116a, 116b, 116c during the picking up and loading procedures discussed above.

As mentioned previously, each of the end effectors 116a, 116b, 116c is arranged one above another in the vertical direction. Therefore, the vertical position and/or height of each of the wafers supported by each of the end effectors 116a, 116b, 116c will be different.

To facilitate simultaneous loading of the wafers onto the rotary chucks 109, each of the rotary chucks 109 may have an adjustable height, and the heights of the rotary chucks 109 may be adjusted to different heights corresponding to the different heights of the respective wafers supported by the respective end effectors 116a, 116b, 116c. For example, each of the rotary chucks 109 may be attached to, or mounted on, a respective actuator that is configured to raise and/or lower the rotary chuck 109.

Alternatively, each of the rotary chucks 109 may be positioned or mounted at a different fixed height corresponding to the different heights of the respective wafers supported by the respective end effectors 116a, 116b, 116c.

FIG. 6 shows a schematic perspective view of a robotic arm 600 that may form part of a system according to an embodiment of the invention. For example, the robotic arm 600 may correspond to the robotic arm 114 of the system 100 discussed above.

The robotic arm 600 has a similar construction to the robotic arm 114 discussed above. In particular, the robotic arm 600 comprises a turret 602 which is connected to an actuator 604 for controlling a height of the robotic arm 600. An upper arm 606 is pivotably connected to the turret 602. The robotic arm 600 further comprises a lower forearm 608 and an upper forearm 610, both of which are pivotably connected to the upper arm 606. Specifically, the lower forearm 608 and the upper forearm 610 are both connected to the upper arm 606 via a first pivot axle (not shown). The lower forearm 608 and the upper forearm 610 can be pivoted independently about the first pivot axle.

A first set of three end effectors 612 is pivotably connected to a working end of the lower forearm 608, and a second set of three end effectors 614 is pivotably connected to a working end of the upper forearm 610. The first set of end effectors 612 is mounted to a pivot axle at the working end of the lower forearm 608, in a manner analogous to how the end effectors 116a, 116b, 116c are mounted at the working end of the first forearm 122 discussed above. Likewise, the second set of end effectors 614 is mounted to a pivot axle at the working end of the upper forearm 610, in a manner analogous to how the end effectors 116a, 116b, 116c are mounted at the working end of the first forearm 122 discussed above.

Accordingly, the end effectors in the first set 612 are pivotable relative to the lower forearm 608 between a transport arrangement and a loading arrangement, and the end effectors in the second set 614 are likewise pivotable relative to the upper forearm 610 between a transport arrangement and a loading arrangement. In FIG. 6, the first set 612 of end effectors are shown in the loading arrangement and the second set 614 of end effectors are shown in their transport arrangement, i.e. the end effectors in the first set 612 are all at different pivot angles with respect to the lower forearm 608 and the end effectors in the second set 614 are all at a same pivot angle with respect to the upper forearm 610. As such, in FIG. 6 the three end effectors in the second set 614 are not distinguishable from one another.

The first set of end effectors 612 and the second set of end effectors 614 may each operate in an analogous manner to the set of end effectors 116a, 116b, 116c discussed above.

When incorporated for example into the system 100, the robotic arm 600 may be configured to use the first set of end effectors 612 to transfer pre-processed wafers from the storage unit 102 to the wafer processing stations, whilst the second set of end effectors 614 may be used to transfer processed wafers from the wafer processing stations back to the storage unit 102. In this manner, different sets of end effectors are used for handling pre-processed wafers and processed wafers, which may avoid contamination of processed wafers via the end effectors. The movements of the robotic arm 600 for picking up and loading wafers using the first set of end effectors 612 and the second set of end effectors 614 may be analogous to the movements described above in relation to the robotic arm 114.

In an alternative embodiment (not shown), the first set of end effectors 612 and the second set of end effectors 614 may both be pivotably mounted on a same forearm of the robotic arm 600. For example, instead of including the lower forearm 608 and the upper forearm 610, the robotic arm 600 may instead include a single forearm which is pivotably connected to the upper arm 606. The single forearm may include a pivot axle at its working end, to which both the first set 612 and the second set 614 of end effectors is pivotably connected. The first set 612 and the second set 614 of end effectors may be connected at opposite ends of the pivot axle, i.e. so that the working end of the single forearm is located between the first set 612 and the second set 614 of end effectors.

Of course, in an alternative embodiment the upper arm and single forearm may be replaced with a single arm.

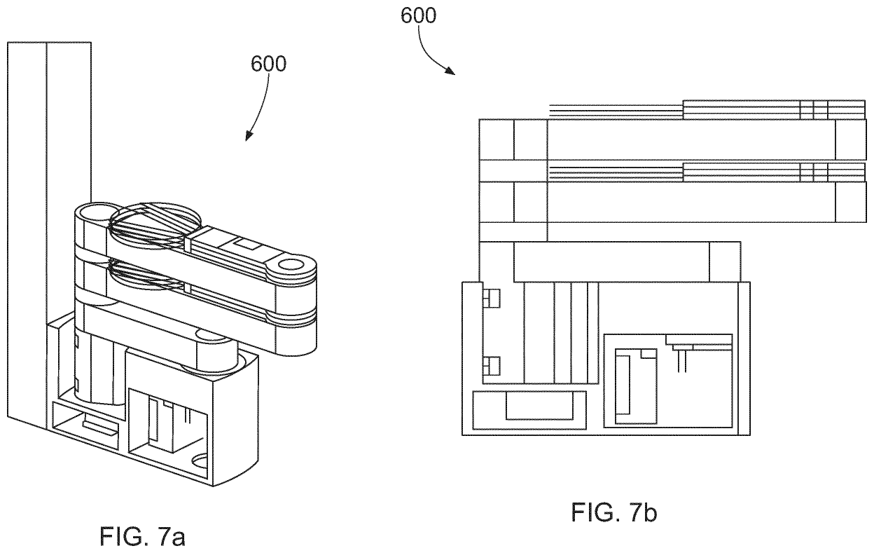

FIGS. 7a and 7b show alternative configurations of the robotic arm 600 of FIG. 6, with both the first set 612 and second set 614 of end effectors in the transport arrangement, and with the lower forearm 608 and upper forearm 610 overlapped.

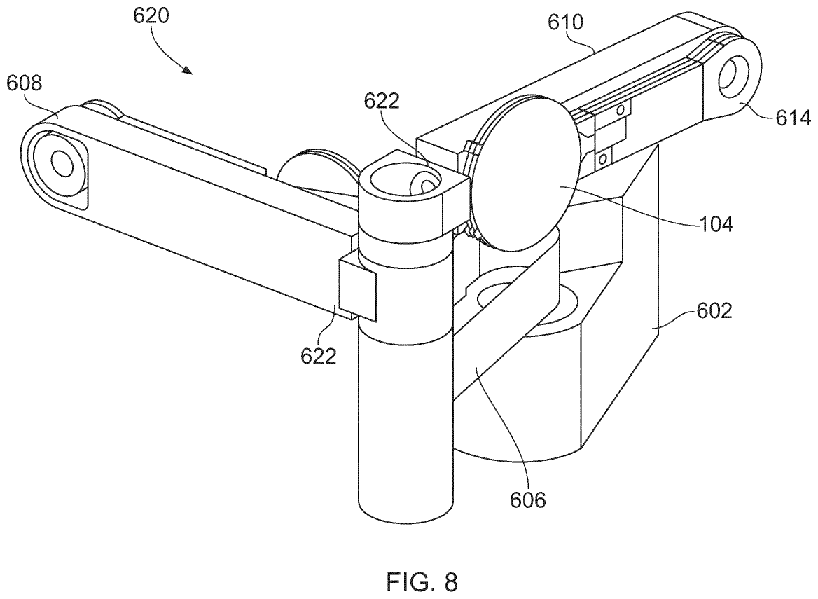

FIG. 8 is a schematic diagram showing a perspective view of a robotic arm 620 that may be part of a system according to an embodiment of the invention. Features corresponding to those illustrated in FIGS. 6, 7a and 7b are indicated using the same reference signs and detailed description thereof is not repeated.

The main difference between the robotic arm 620 of FIG. 8 and the robotic arm 600 of FIG. 6 is that in the robotic arm 620 of FIG. 8, each of the lower forearm 608 and upper forearm 610 is rotatable around its longitudinal axis so as to flip the first set 612 or second set 614 of end effectors.

In particular, each of the lower forearm 608 and upper forearm 610 comprises, or is provided with, a respective rotatable or pivotable joint 622 at which the forearm can be rotated around its longitudinal axis.

As discussed above, each of the end effectors may comprise a retaining mechanism for retaining the wafer on the end effector when the respective forearm is flipped, for example a plurality of gripping elements or gripping pins that grip the wafer.

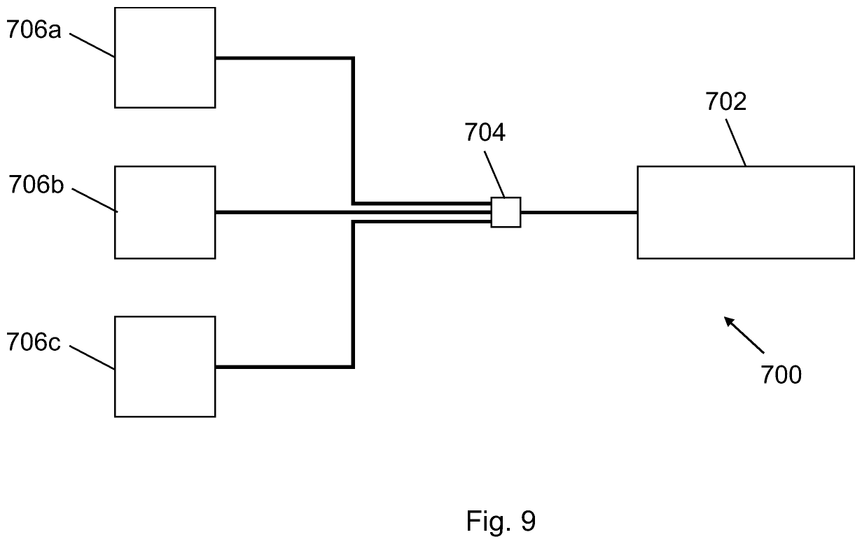

FIG. 9 is a schematic diagram depicting a fluid supply system 700 that may be used as part of a wafer-processing system according to an embodiment of the invention. For example, the fluid supply system 700 may be used as part of the system 100 described above. The fluid supply system 700 is configured to supply fluid to a set of three wafer processing stations.

The fluid supply system 700 includes a fluid source 702, an outlet of which is connected to a supply valve 704. The supply valve 704 may alternatively be, or be referred to as, a flow controller or a flow rate controller that controls a flow or a flow rate of the fluid (liquid).

The fluid supply 702 may comprise a fluid reservoir or tank that contains a fluid for use by a wafer processing station during processing of a wafer. For example, the fluid supply 702 may contain a cleaning fluid (e.g. IPA, acetone), a rinsing fluid (e.g. de-ionised water), or any etching fluid that can be used for processing a wafer. The fluid is typically a liquid.

The fluid supply 702 may comprise a pump for pumping the fluid from the fluid supply 702 to the set of three wafer processing stations.

The supply valve 704 is connected in parallel to three fluid dispensers 706a, 706b, 706c. For example, the fluid dispensers 706a, 706b, 706c may correspond to the fluid dispensers 112 located in each of the wafer processing stations in the first set or the second set of system 100. Thus, each of the fluid dispensers 706a, 706b, 706c may comprise a nozzle (or fluid outlet) which is arranged on an arm, so that the nozzle is positionable over a rotary chuck of the wafer processing station.

The supply valve 704 may comprise any suitable type of valve, such as a needle valve or ball valve, and is configured to control supply of fluid from the fluid source 702 to the three fluid dispensers 706a, 706b, 706c. Thus, when the supply valve 704 is closed, no fluid is supplied to the fluid dispensers 706a, 706b, 706c, and when the supply valve 704 is open, fluid is supplied to each of the fluid dispensers 706a, 706b, 706c from the fluid source 702. Thus, a single supply valve (i.e. supply valve 704) can be controlled to control simultaneous supply of fluid from the fluid source 702 to fluid dispensers located in three wafer processing stations. This facilitates simultaneous (i.e. parallel) processing of three wafers, and reduces an amount of tubing (or pipework) and number of valves required to control fluid supply to the wafer processing stations.

The supply valve 704 may be configured to control a flow rate of the fluid from the fluid source 702.

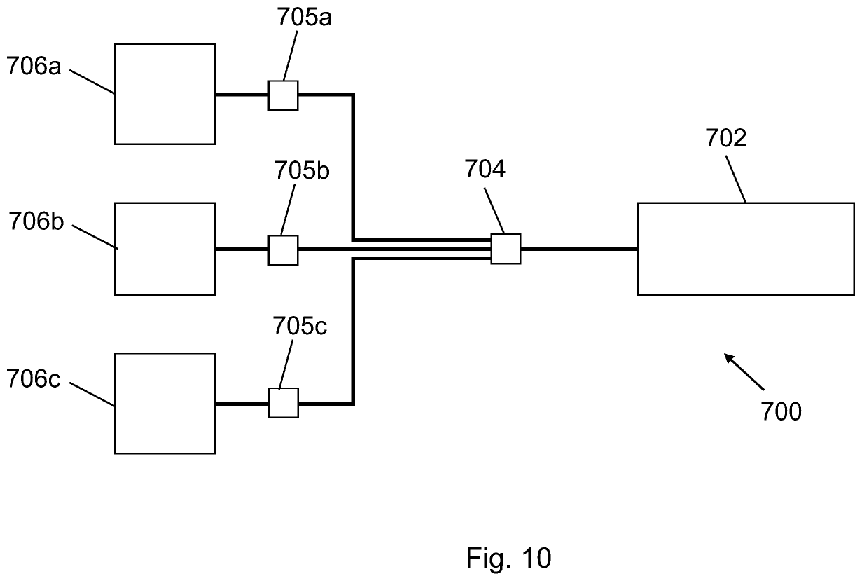

In an alternative embodiment illustrated in FIG. 10, separate supply valves may additionally be provided for each of the fluid dispensers or processing stations. In particular, as illustrated in FIG. 10, a respective supply valve 705a, 705b, 705c is provided for each of the processing stations. The respective supply valves 705a, 705b, 705c may each be an on/off valve, for example a shut on/off valve, that is used to switch on or off the flow of the fluid to the respective processing station and fluid dispenser 706a, 706b, 706c.

Therefore, the respective supply valve 705a, 705b, 705c, may control whether or not fluid is supplied to the processing station, and the shared supply valve 704 may control a flow rate of the fluid.

The respective supply valve may be provided in the processing station, or in a respective flow path leading from the shared supply valve to the processing station.

As an example, the fluid supply system 700 may be used to supply fluid to the wafer processing stations 108a, 108b, 108c in the first set of the system 100. Then, when wafers 104 are loaded onto the rotary chucks 109 of the wafer processing stations 108a, 108b, 108c, the valve 704 can be operated to control dispensing of fluid onto the wafers during processing of the wafers.

The fluid supply system illustrated in FIG. 9 may be used to dispense a liquid such as a rinsing liquid or a cleaning liquid onto a backside of a wafer being processed, for example.

The fluid supply system 700 may be adapted to supply fluid to multiple sets of wafer processing stations. This may be achieved by using a respective supply valve to control supply of fluid to each set of wafer processing stations. In other words, multiple fluid supply valves may be connected in parallel to the fluid source 702. Each supply valve may then be connected in parallel to the fluid dispensers of a respective set of wafer processing stations. Alternatively, instead of sharing a single fluid source 702 between multiple sets of wafer processing stations, a respective fluid source may be used for each set of wafer processing stations.

In some cases, a wafer processing system of the invention may include multiple fluid supply systems, for example where multiple (e.g. two or more) fluids are used by the wafer processing stations. Each fluid supply system may be configured as system 700, with the fluid source 702 of each fluid supply system containing a different fluid. Each processing station may then correspond a respective fluid dispenser, one for each of the multiple fluid supply systems. Then, the supply valve of each fluid supply system can be operated, in order to control supply of the different fluids to the set of wafer processing stations.

An analogous architecture to the fluid supply system 700 may be used for a suction (or vacuum) system used as part of a wafer-processing system according to the invention.

In an alternative arrangement, the shared supply valve 704 may be omitted and each of the fluid dispensers 706a, 706b, 706c may instead be provided with both a respective supply valve 705a, 705b, 705c and a respective liquid flow controller or liquid flow rate controller 704a, 704b, 704c. The respective supply valve 705a, 705b, 705c may be an on/off valve that either allows flow of the fluid to the fluid dispenser 706a, 706b, 706c or prevents the flow of the fluid. The respective liquid flow controller or liquid flow rate controller 704a, 704b, 704c may control a flow rate of the fluid supplied to the fluid dispenser 706a, 706b, 706c when the respective supply valve 705a, 705b, 705c is opened to allow flow of the liquid.

This arrangement may be used for fluid dispensers that dispense fluid onto a top side of a wafer being processed, for example. The fluid may be a processing liquid, or a rinse liquid or a cleaning liquid, for example.

An analogous arrangement may also be used for a suction (or vacuum) system used as part of a wafer-processing system according to the invention.

As discussed above in relation to system 100, the rotary chucks 109 of the wafer processing stations may each include suction ports for applying suction to suck collected liquid. In place of the fluid source 702, the suction system may include a suction source (e.g. a fan or vacuum pump), whilst in place of the fluid dispensers 706a, 706b, 706c the suction system may include suction ports of wafer processing stations. The valve 704 may then be used to control application of suction from the suction source 702 to the suction ports 706a, 706b, 706c. The suction ports may be located in a drain line, and/or in a collection container, for example.

In the above description, embodiments including sets of three wafer processing stations and sets of three end effectors are discussed. It will be understood that other embodiments may include sets with a different number (for example more than three) of wafer processing stations and end effectors. In general, the number of end effectors in a set of end effectors may correspond to the number of wafer processing stations in a set of wafer processing stations. In this manner, each end effector in a set of end effectors may be associated with a respective wafer processing station in a set of wafer processing stations.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

1. A system for processing wafer-shaped articles, the system comprising:
three or more processing stations; and
a robotic arm comprising a first set of end effectors including three or more end effectors;
wherein the robotic arm is configured to pick up, from a storage unit configured to store a plurality of wafer-shaped articles, a respective wafer-shaped article with each of the three or more end effectors, and load one of the respective wafer-shaped articles into each of the three or more processing stations.

2. The system according to claim 1, wherein the robotic arm is configured to simultaneously load the respective wafer-shaped articles into each of the three or more processing stations.

3. The system according to claim 1, wherein the robotic arm is configured to simultaneously pick up the respective wafer-shaped articles with each of the three or more end effectors from the storage unit.

4. The system according to claim 1, wherein the three or more processing stations are configured to operate simultaneously.

5. The system according to claim 1, wherein each of the three or more end effectors is pivotably mounted about a first common axis.

6. The system according to claim 5, wherein the three or more end effectors are configured to be aligned to pick up the respective wafer-shaped articles from the storage unit.

7. The system according to claim 5, wherein the three or more end effectors are configured to be fanned-out to load the respective wafer-shaped articles into each of the three or more processing stations.

8. The system according to claim 5, wherein the three or more end effectors are configured to be at different pivot angles about the first common axis to load the respective wafer-shaped articles into each of the three or more processing stations.

9. The system according to claim 5, wherein the three or more end effectors are arranged one above another along the first common axis.

10. The system according to claim 1, wherein the robotic arm comprises a first forearm, and wherein the three or more end effectors are pivotably mounted to the first forearm, the three or more end effectors being pivotable relative to the first forearm about a first common axis.

11. The system according to claim 10, wherein the three or more end effectors are pivotable relative to the first forearm between a first arrangement where the three or more end effectors are aligned with one another along the first common axis, and a second arrangement where the three or more end effectors are at different pivot angles about the first common axis.

12. The system according to claim 11, wherein the robotic arm is configured to load the respective wafer-shaped articles into each of the three or more processing stations by:
moving the first forearm towards the three or more processing stations, with the three or more end effectors in the first arrangement; and
moving the three or more end effectors from the first arrangement to the second arrangement, such that each of the three or more end effectors is above an associated one of the three or more processing stations.

13. The system according to claim 12, wherein:
each of the three or more processing stations comprises a rotary chuck having a set of retaining pins for retaining the respective wafer-shaped article; and
each rotary chuck is configured to rotate when the three or more end effectors are moved to the second arrangement, to prevent contact between the set of retaining pins and the associated end effector.

14. The system according to claim 13, wherein each rotary chuck is configured to rotate in synchronisation with the movement of the associated end effector.

15. The system according to claim 1, wherein the three or more processing stations are arranged at different vertices of a triangle.

16. The system according to claim 1, wherein the system further comprises a holding unit configured to hold the storage unit.

17. The system according to claim 16, wherein the system comprises a plurality of the holding units.

18. The system according to claim 1, wherein the robotic arm is configured to flip the first set of end effectors.

19. The system according to claim 1, wherein:
the robotic arm further comprises a second set of end effectors including three or more end effectors; and
wherein the robotic arm is configured to pick up, with each end effector in the second set, a respective wafer-shaped article from each of the three or more processing stations, and load the respective wafer-shaped articles into a storage unit.

20. The system according to claim 19, wherein the robotic arm is configured to simultaneously pick up the respective wafer-shaped articles with each of the three or more end effectors of the second set of end effectors from each of the three or more processing stations.

21. The system according to claim 19, wherein the robotic arm is configured to simultaneously load the respective wafer-shaped articles into the storage unit.

22. The system according to claim 19, wherein the robotic arm comprises a second forearm, and wherein the three or more end effectors in the second set are pivotably mounted to the second forearm, the three or more end effectors being pivotable relative to the second forearm about a second common axis.

23. The system according to claim 19, wherein the robotic arm is configured to flip the second set of end effectors.

24. The system according to claim 1, further comprising a shutter, the shutter being movable between a closed state in which it isolates the robotic arm from the three or more processing stations, and an open state in which it allows the robotic arm to access the three or more processing stations.

25. The system according to claim 1, comprising a first set of three or more processing stations and a second set of three or more processing stations, the first set and the second set of three or more processing stations being arranged adjacent to one another, wherein the robotic arm is configured to selectively load the respective wafer-shaped articles into the three or more processing stations of the first set or the three or more processing stations of the second set.

26. The system according to claim 1, comprising two or more levels arranged one above another, wherein each level comprises a respective set of three or more processing stations, wherein the robotic arm is configured to selectively load the respective wafer-shaped articles into the set of three or more processing stations of one of the two or more levels.

27. A method for processing wafer-shaped articles, the method comprising:
using a robotic arm comprising a first set of end effectors including three or more end effectors, picking up from a storage unit a respective wafer-shaped article with each of the three or more end effectors; and
loading, with the robotic arm, one of the respective wafer-shaped articles into each of three or more processing stations.

28. The method according to claim 27, wherein the respective wafer-shaped articles are simultaneously loaded into each of the three or more processing stations.

29. The method according to claim 27, wherein the respective wafer-shaped articles are simultaneously picked up with each of the three or more end effectors.

30. The method according to claim 27, further comprising:
following the loading of the respective wafer-shaped articles into each of the three or more processing stations, operating the three processing stations to process the respective wafer-shaped articles.

31. The method according to claim 30, wherein the robotic arm further comprises a second set of end effectors including three or more end effectors, the method further comprising:
following the processing of the respective wafer-shaped articles, picking up, with each end effector in the second set, one of the respective wafer-shaped articles from one of the three or more processing stations; and
loading the respective wafer-shaped articles into a storage unit.

32. A robotic arm comprising a first set of end effectors including three or more end effectors;
wherein the robotic arm is configured to pick up, from a storage unit configured to store a plurality of wafer-shaped articles, a respective wafer-shaped article with each of the three or more end effectors, and load one of the respective wafer-shaped articles into each of three or more processing stations.

33. The robotic arm according to claim 31, wherein the robotic arm is configured to flip the first set of effectors.
